(19) United States
(12) Patent Application Publication
(10) Pub. No.: US 2026/0113015 A1
(43) Pub. Date: Apr. 23, 2026

(54) ACOUSTIC WAVE DEVICE AND FILTER DEVICE

(71) Applicant: Murata Manufacturing Co., Ltd., Nagaokakyo-shi (JP)

(72) Inventors: Takuya YABU, Nagaokakyo-shi (JP); Kentaro NAKAMURA, Nagaokakyo-shi (JP); Ryo NAKAGAWA, Nagaokakyo-shi (JP)

(21) Appl. No.: 19/426,527

(22) Filed: Dec. 19, 2025

Related U.S. Application Data
(63) Continuation of application No. PCT/JP2024/019833, filed on May 30, 2024.

(30) Foreign Application Priority Data
Jun. 21, 2023 (JP) 2023-101305

(51) Int. Cl. H03H 9/13; H03H 9/56

(52) U.S. Cl. CPC H03H 9/133; H03H 9/568

(57) ABSTRACT

An acoustic wave device includes a piezoelectric layer and an IDT electrode including first and second busbars and first and second electrode fingers. A virtual line connecting tip portions of the second electrode fingers is defined as a first envelope, and a virtual line connecting tip portions of the first electrode fingers is defined as a second envelope, and a region between the first and second envelopes is an intersection region. The intersection region includes parallel regions in which the first and second electrode fingers extend in parallel and a non-parallel region in which directions in which the first and second electrode fingers extend intersect each other. The parallel and non-parallel regions are alternately arranged in the intersection region. The first and second electrode fingers linearly extend in the parallel and non-parallel regions, and are bent at the boundaries between the parallel and non-parallel regions.

### CROSS REFERENCE TO RELATED APPLICATIONS

This application claims the benefit of priority to Japanese Patent Application No. 2023-101305 filed on Jun. 21, 2023 and is a Continuation Application of PCT Application No. PCT/JP2024/019833 filed on May 30, 2024. The entire contents of each application are hereby incorporated herein by reference.

### BACKGROUND OF THE INVENTION

### 1. Field of the Invention

The present invention relates to acoustic wave devices and filter devices.

### 2. Description of the Related Art

Conventionally, acoustic wave devices have been widely used in filters for cellular phones and the like. An example of the acoustic wave device is disclosed in International Publication No. WO 2011/108229. In this acoustic wave device, an interdigital transducer (IDT) electrode is disposed on a piezoelectric substrate. The shapes of a plurality of electrode fingers of the IDT electrode include curved shapes. Specifically, each electrode finger extends along a curved line from the center of a region in which the plurality of electrode fingers intersect to a common electrode.

In the IDT electrode of the acoustic wave device described in International Publication No. WO 2011/108229, the electrode finger pitch at a central portion in a direction in which the plurality of electrode fingers extend is narrower than the electrode finger pitch at end portions in this direction. However, in this acoustic wave device, an effect of reducing or preventing a response of unwanted waves is not sufficient.

### SUMMARY OF THE INVENTION

Example embodiments of the present invention provide acoustic wave devices and filter devices that each effectively reduce or prevent unwanted waves.

An acoustic wave device according to an example embodiment of the present invention includes a piezoelectric substrate including a piezoelectric layer and an IDT electrode on the piezoelectric layer and including a pair of busbars and a plurality of electrode fingers. The pair of busbars include a first busbar and a second busbar opposite to each other, and the plurality of electrode fingers include a plurality of first electrode fingers and a plurality of second electrode fingers. One end of each of the plurality of first electrode fingers is connected to the first busbar. One end of each of the plurality of second electrode fingers is connected to the second busbar. The plurality of first electrode fingers and the plurality of second electrode fingers are interdigitated with each other. A virtual line connecting tip portions of the plurality of second electrode fingers is defined as a first envelope, and a virtual line connecting tip portions of the plurality of first electrode fingers is defined as a second envelope, and a region between the first envelope and the second envelope in the IDT electrode is an intersection region. The intersection region includes a plurality of parallel regions in which the plurality of first electrode fingers and the plurality of second electrode fingers extend in parallel and a non-parallel region in which directions in which the plurality of first electrode fingers and the plurality of second electrode fingers extend intersect each other. The parallel region and the non-parallel region are alternately provided in at least a portion of the intersection region. The plurality of first electrode fingers and the plurality of second electrode fingers each linearly extend in the plurality of parallel regions and the non-parallel region and are each bent at boundaries between the parallel region and the non-parallel region.

A filter device according to an example embodiment of the present invention includes a plurality of acoustic wave resonators, and at least one of the acoustic wave resonators includes an acoustic wave device according to an example embodiment of the present invention.

Example embodiments of the present invention provide acoustic wave devices and filter devices that each reduce or prevent unwanted waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a simplified plan view of an acoustic wave device according to a first example embodiment of the present invention.

FIG. 2 is a schematic sectional view taken along line I-I in FIG. 1.

FIG. 3 is a schematic plan view showing an enlarged portion of the acoustic wave device according to the first example embodiment of the present invention.

FIG. 4 is a schematic plan view showing parallel regions and non-parallel regions in the first example embodiment of the present invention.

FIG. 5 is a diagram showing reverse-velocity surfaces of acoustic waves propagating through a first piezoelectric substrate and a second piezoelectric substrate.

FIG. 6 is a diagram showing reverse-velocity surfaces of a longitudinal wave, a fast transversal wave, and a slow transversal wave in the first piezoelectric substrate.

FIG. 7 is a diagram showing a relationship between the absolute value of an excitation angle |θ_{C_prop}| and a rate of change Δpitch of an electrode finger pitch in an IDT electrode in the first example embodiment of the present invention.

FIG. 8 is a simplified plan view of the acoustic wave device for explaining a dimension M1, a dimension M2, an angle α1, and an angle α2 in the first example embodiment of the present invention.

FIG. 9 is a diagram showing a relationship between the absolute value of the excitation angle |θ_{C_prop}| and a duty ratio in the IDT electrode in a first modification of the first example embodiment of the present invention.

FIG. 10 is a diagram showing a relationship between the absolute value of the excitation angle |θ_{C_prop}| and the thickness of electrode fingers in the IDT electrode in a second modification of the first example embodiment of the present invention.

FIG. 11 is a schematic elevational cross-sectional view of an acoustic wave device according to a third modification of the first example embodiment of the present invention.

FIG. 12 is a diagram showing a relationship between the absolute value of the excitation angle |θ_{C_prop}| and the thickness of a portion covering an intersection region in a dielectric film in the third modification of the first example embodiment of the present invention.

FIG. 13 is a diagram showing a relationship between the absolute value of the excitation angle |θ_{C_prop}| and the thickness of the portion covering the intersection region in the dielectric film in a fourth modification of the first example embodiment of the present invention.

FIG. 14 is a schematic plan view of an acoustic wave device according to a second example embodiment of the present invention.

FIG. 15 is a schematic plan view of an acoustic wave device according to a third example embodiment of the present invention.

FIG. 16 is a schematic plan view of an acoustic wave device according to a fourth example embodiment of the present invention.

FIG. 17 is a schematic plan view of an acoustic wave device according to a modification of the fourth example embodiment of the present invention.

FIG. 18 is a schematic plan view of an acoustic wave device according to a fifth example embodiment of the present invention.

FIG. 19 is a simplified plan view of the acoustic wave device according to the fifth example embodiment of the present invention.

FIG. 20 is a schematic plan view of an acoustic wave device of a comparative example.

FIG. 21 is a diagram showing an impedance frequency characteristic in the fourth example embodiment, the fifth example embodiment, and the comparative example of the present invention.

FIG. 22 is a diagram showing return loss in the fourth example embodiment and the fifth example embodiment of the present invention.

FIG. 23 is a diagram showing a phase characteristic on the lower frequency side relative to a resonant frequency in the fourth example embodiment, the fifth example embodiment, and the comparative example of the present invention.

FIG. 24 is a schematic plan view for explaining the acoustic wave device of the modification of the fourth example embodiment of the present invention.

FIG. 25 is a schematic plan view of an acoustic wave device according to a sixth example embodiment of the present invention.

FIG. 26 is a schematic plan view of an acoustic wave device according to a seventh example embodiment of the present invention.

FIG. 27 is a schematic plan view of an acoustic wave device according to an eighth example embodiment of the present invention.

FIG. 28 is a schematic enlarged plan view showing vicinities of a first edge region and a second edge region in the eighth example embodiment of the present invention.

FIG. 29 is a schematic plan view of an acoustic wave device according to a first modification of the eighth example embodiment of the present invention.

FIG. 30 is a schematic enlarged plan view showing vicinities of the first edge region and the second edge region in a second modification of the eighth example embodiment of the present invention.

FIG. 31A is a schematic sectional view along an electrode finger extension direction showing sections in vicinities of the first edge region, the second edge region, and a central region in a first electrode finger in a third modification of the eighth example embodiment of the present invention, and FIG. 31B is a schematic sectional view along the electrode finger extension direction showing sections in vicinities of the first edge region, the second edge region, and the central region in a second electrode finger in the third modification of the eighth example embodiment of the present invention.

FIG. 32 is a schematic elevational cross-sectional view of an acoustic wave device according to a ninth example embodiment of the present invention.

FIG. 33 is a schematic elevational cross-sectional view of an acoustic wave device according to a first modification of the ninth example embodiment of the present invention.

FIG. 34 is a schematic elevational cross-sectional view of an acoustic wave device according to a second modification of the ninth example embodiment of the present invention.

FIG. 35 is a schematic elevational cross-sectional view of an acoustic wave device according to a tenth example embodiment of the present invention.

FIG. 36 is a schematic elevational cross-sectional view of an acoustic wave device according to an eleventh example embodiment of the present invention.

FIG. 37 is a schematic elevational cross-sectional view of an acoustic wave device according to a first modification of the eleventh example embodiment of the present invention.

FIG. 38 is a schematic elevational cross-sectional view of an acoustic wave device according to a second modification of the eleventh example embodiment of the present invention.

FIG. 39 is a schematic elevational cross-sectional view of an acoustic wave device according to a third modification of the eleventh example embodiment of the present invention.

FIG. 40 is a circuit diagram of a filter device according to a twelfth example embodiment of the present invention.

### DETAILED DESCRIPTION OF THE EXAMPLE EMBODIMENTS

In the following, the present invention is made apparent by describing example embodiments of the present invention with reference to the drawings.

The respective example embodiments described in the present specification are provided as examples, and partial replacement or combination of configurations between different example embodiments is possible.

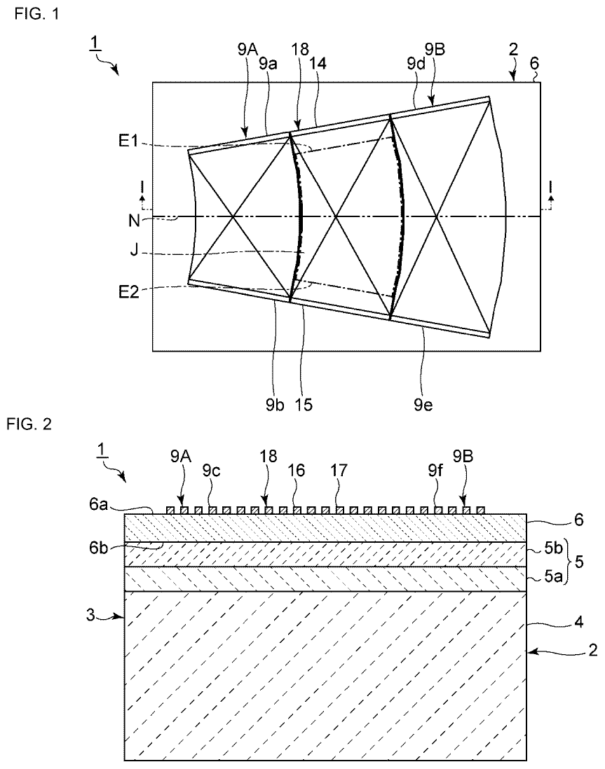

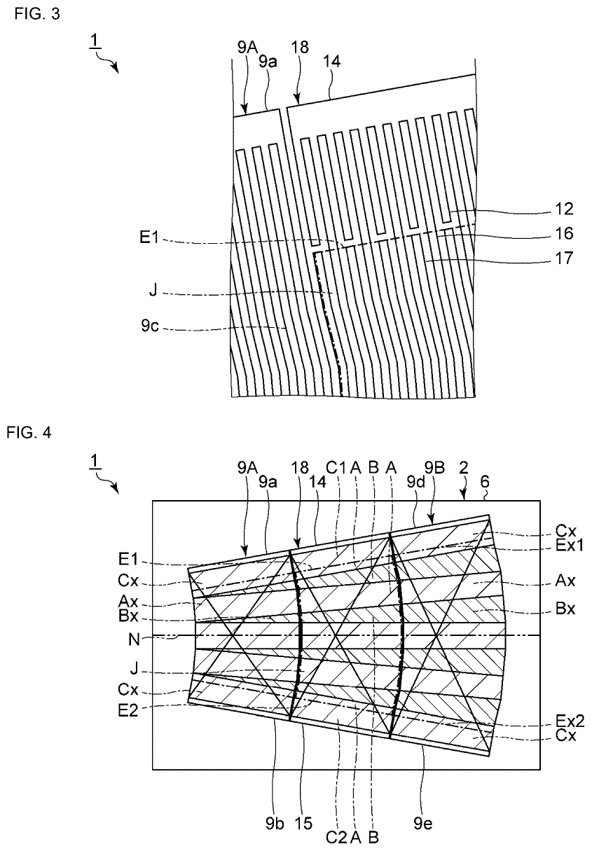

FIG. 1 is a simplified plan view of an acoustic wave device according to a first example embodiment of the present invention. FIG. 2 is a schematic sectional view taken along line I-I in FIG. 1. FIG. 3 is a schematic plan view showing an enlarged part of the acoustic wave device according to the first example embodiment. In FIG. 1, an electrode configuration other than busbars and reflector busbars, which are described later, is shown in a simplified manner by figures including two diagonal lines. The same applies to the simplified plan views other than FIG. 1.

As shown in FIGS. 1 and 2, an acoustic wave device 1 includes a piezoelectric substrate 2. The piezoelectric substrate 2 is a substrate having piezoelectricity. As shown in FIG. 2, the piezoelectric substrate 2 includes a support 3 and a piezoelectric layer 6. Specifically, the support 3 includes a support substrate 4 and an intermediate layer 5. The intermediate layer 5 includes a first layer 5a and a second layer 5b. The first layer 5a is disposed on the support substrate 4. The second layer 5b is disposed on the first layer 5a. The piezoelectric layer 6 is disposed on the second layer 5b. The layer configuration of the piezoelectric substrate 2 is not limited to that described above. For example, the intermediate layer 5 may be a single-layer dielectric film. Alternatively, the piezoelectric substrate 2 may be a substrate including only the piezoelectric layer 6.

A piezoelectric single crystal is used as a material of the piezoelectric layer 6 of the acoustic wave device 1. The piezoelectric layer 6 includes a propagation axis. In the piezoelectric layer 6, the propagation axis is in the direction of X-propagation. The direction in which the propagation axis extends is parallel or substantially parallel to a dash-dot-dot line N shown in FIG. 1.

As shown in FIG. 2, the piezoelectric layer 6 includes a first main surface 6a and a second main surface 6b. The first main surface 6a and the second main surface 6b are opposite to each other. Of the first main surface 6a and the second main surface 6b, the second main surface 6b is located on the support substrate 4 side. An IDT electrode 18 is disposed on the first main surface 6a of the piezoelectric layer 6.

An acoustic wave is excited by applying an alternating voltage to the IDT electrode 18. Specifically, for example, an SH mode is excited as a main mode. In this case, for example, a Rayleigh wave is an unwanted wave. However, the main mode is not limited to the SH mode.

As shown in FIG. 1, the IDT electrode 18 includes a pair of busbars. Specifically, the pair of busbars include a first busbar 14 and a second busbar 15. The first busbar 14 and the second busbar 15 are opposite to each other. As shown in FIG. 3, the IDT electrode 18 includes a plurality of electrode fingers. Specifically, the plurality of electrode fingers include a plurality of first electrode fingers 16 and a plurality of second electrode fingers 17. One end of each of the first electrode fingers 16 is connected to the first busbar 14. One end of each of the second electrode fingers 17 is connected to the second busbar 15.

The first electrode fingers 16 and the second electrode fingers 17 each include a base end portion and a tip portion. The base end portion of the first electrode finger 16 is a portion connected to the first busbar 14. The base end portion of the second electrode finger 17 is a portion connected to the second busbar 15. The first electrode fingers 16 and the second electrode fingers 17 are interdigitated with each other. Hereinafter, the first electrode finger 16 and the second electrode finger 17 are sometimes referred to simply as electrode finger. The first busbar 14 and the second busbar 15 are sometimes referred to simply as busbar.

The tip portions of the first electrode fingers 16 and the second electrode fingers 17 each include a tip. As shown in FIG. 3, a virtual line connecting the tips of the second electrode fingers 17 is defined as a first envelope E1. Similarly, a virtual line connecting the tips of the first electrode fingers 16 is defined as a second envelope E2 shown in FIG. 1.

A region between the first envelope E1 and the second envelope E2 is an intersection region J. Specifically, the intersection region J is a region surrounded by an edge portion of the electrode finger at one end in the direction in which the plurality of electrode fingers are arranged among the plurality of electrode fingers, an edge portion of the electrode finger at the other end, the first envelope E1, and the second envelope E2. Thus, the first envelope E1 corresponds to an edge portion of the intersection region J on the first busbar 14 side. The second envelope E2 corresponds to an edge portion of the intersection region J on the second busbar 15 side. In the intersection region J, as viewed in a direction in which the first envelope E1 or the second envelope E2 extends, adjacent electrode fingers overlap each other.

In the present specification, “plan view” refers to viewing from a direction corresponding to the upper side in FIG. 2. In FIG. 2, for example, of the support substrate 4 side and the piezoelectric layer 6 side, the piezoelectric layer 6 side is the upper side.

In the acoustic wave device 1, shapes of the plurality of first electrode fingers 16 and the plurality of second electrode fingers 17 in plan view are shapes bent at a plurality of nodes. Specifically, the shapes of the first electrode fingers 16 and the second electrode fingers 17 in plan view are shapes in which straight lines are connected to each other at the respective nodes. In the present example embodiment, each electrode finger is bent to be convex in the right direction in FIG. 1 or 3 as a whole. The shape of each electrode finger in plan view can be approximated by a circular arc, an elliptical arc, or a parabola, for example.

FIG. 4 is a schematic plan view showing parallel regions and non-parallel regions in the first example embodiment. In FIG. 4, each region is shown with hatching. The same hatching is applied to the parallel region and a region obtained by extending the parallel region, which are described later. The same hatching is applied to the non-parallel region and a region obtained by extending the non-parallel region, which are described later. A dash-dot line Ex1 in FIG. 4 is an extension line of the first envelope E1. Meanwhile, a dash-dot line Ex2 is an extension line of the second envelope E2.

The intersection region J includes a plurality of parallel regions A and a plurality of non-parallel regions B. Specifically, the parallel region A is a region in which the plurality of first electrode fingers 16 and the plurality of second electrode fingers 17 extend in parallel. In the present specification, the expression “a plurality of electrode fingers extend in parallel” includes not only a case in which the electrode fingers extend strictly in parallel but also a case in which they extend substantially in parallel. Specifically, for example, even when an angle between a direction in which one of the electrode fingers extends and a direction in which the other electrode finger extends is within about ±1°, these electrode fingers are regarded as extending in parallel with each other. On the other hand, the non-parallel region B is a region in which directions in which the plurality of first electrode fingers 16 and the plurality of second electrode fingers 17 extend intersect each other. The intersection region J is only required to include at least two parallel regions A and at least one non-parallel region B.

In the IDT electrode 18, all the parallel regions A and all the non-parallel regions B each include a portion of all of the first electrode fingers 16 and a portion of all of the second electrode fingers 17. However, the parallel region A is not necessarily required to include a portion of all of the first electrode fingers 16 and a portion of all of the second electrode fingers 17. The same applies to the non-parallel region B.

The present example embodiment includes the following configurations. (1) The parallel region A and the non-parallel region B are alternately disposed. (2) The plurality of first electrode fingers 16 and the plurality of second electrode fingers 17 each linearly extend in the plurality of parallel regions A and the non-parallel region B, and are each bent at the boundaries between the parallel region A and the non-parallel region B. That is, each electrode finger is bent at the boundary as a node. By the acoustic wave device 1 having the above-described configuration, unwanted waves can be effectively reduced or prevented in the acoustic wave device 1. Details of the configuration of the IDT electrode 18 and details of the above advantageous effect are described below.

The shapes of the plurality of first electrode fingers 16 and the plurality of second electrode fingers 17 in plan view are shapes bent at a plurality of nodes. Thus, in the intersection region J of the IDT electrode 18, the excitation direction of an acoustic wave is not uniform.

Specifically, the excitation direction of the acoustic wave at any portion of any electrode finger among the plurality of first electrode fingers 16 and the plurality of second electrode fingers 17 in the intersection region J is one of the following first to third directions. The first direction is a direction perpendicular or substantially perpendicular to the direction in which this electrode finger extends. The second direction is a direction of the shortest distance between this electrode finger and the first electrode finger 16 or the second electrode finger 17 adjacent to this electrode finger. The third direction is a vector direction of an electric field generated between this electrode finger and the first electrode finger 16 or the second electrode finger 17 adjacent to this electrode finger.

In each parallel region A, the excitation direction of the acoustic wave is the first direction. Further, when the direction in which the plurality of first electrode fingers 16 and the plurality of second electrode fingers 17 extend is defined as an electrode finger extension direction, the electrode finger extension directions differ from each other among the plurality of parallel regions A. Thus, the excitation direction of the acoustic wave is not uniform in the intersection region J.

An angle formed between the excitation direction of the acoustic wave and the direction in which the propagation axis of the piezoelectric layer 6 extends is defined as an excitation angle θ_{C_prop}. A portion indicated by the dash-dot-dot line N in FIG. 4 is a portion where the excitation angle θ_{C_prop} is 0°. Thus, θ_{C_prop}=0° in the parallel region A through which the dash-dot-dot line N passes. On the other hand, in each parallel region A through which the dash-dot-dot line N does not pass, the excitation angle θ_{C_prop} is not 0° in the present example embodiment.

In the present specification, the positive direction of the excitation angle θ_{C_prop} is defined as a counterclockwise direction in plan view. Specifically, a direction from the second busbar 15 side toward the first busbar 14 side is the above positive direction.

In the acoustic wave device 1, the direction in which the propagation axis extends is the direction of X-propagation. However, the direction in which the propagation axis extends is not limited thereto. The direction in which the propagation axis extends may be, for example, the direction of about 90° X-propagation, or may be a direction perpendicular or substantially perpendicular to any of the electrode finger extension directions in the IDT electrode 18.

In the intersection region J of the present example embodiment, the plurality of parallel regions A and the plurality of non-parallel regions B are alternately arranged in the direction in which the first busbar 14 and the second busbar 15 are opposite to each other. Further, the excitation angles θ_{C_prop} differ from each other among the plurality of parallel regions A. In portions where the excitation angles θ_{C_prop} differ from each other, propagation characteristics of unwanted waves differ from each other. Accordingly, the unwanted waves can be dispersed, and can be effectively reduced or prevented.

In the present example embodiment, resonant frequencies or anti-resonant frequencies substantially coincide with each other throughout the entire or substantially the entire intersection region J. Thus, a resonance characteristic of the acoustic wave device 1 can be more reliably made favorable. In the present specification, the expression “one frequency and the other frequency substantially coincide with each other” means that the absolute value of the difference between the two frequencies is about 10% or less with respect to a reference frequency. The reference frequency refers to a frequency when the excitation angle θ_{C_prop} is 0°.

In the present example embodiment, the absolute value of the difference between the resonant frequencies of the parallel region A and the non-parallel region B, or the absolute value of the difference between the anti-resonant frequencies thereof, is, for example, about 2% or less with respect to the reference frequency. However, it is preferable that, throughout the entire or substantially the entire intersection region J, the absolute value of the difference between the highest resonant frequency and the lowest resonant frequency of the main mode is, for example, about 2% or less with respect to the reference frequency, and more preferably about 1% or less. Alternatively, it is preferable that, throughout the entire or substantially the entire intersection region J, the absolute value of the difference between the highest anti-resonant frequency and the lowest anti-resonant frequency of the main mode is, for example, about 2% or less with respect to the reference frequency, and more preferably about 1% or less. In these cases, the resonance characteristic of the acoustic wave device 1 can be even more reliably made favorable.

Because the resonant frequencies or the anti-resonant frequencies substantially coincide with each other throughout the entire or substantially the entire intersection region J, unwanted waves can be further reduced or prevented. Details of this are described below.

The phase velocity of the acoustic wave has dependence on the excitation angle θ_{C_prop} in the intersection region, and exhibits inherent characteristics depending on a configuration of the substrate. The inverse number of the phase velocity corresponds to the reverse-velocity surface. Thus, a relationship between the excitation angle θ_{C_prop} and the phase velocity is substantially the same as the reverse-velocity surface of the piezoelectric substrate. Therefore, examples of the reverse-velocity surfaces of piezoelectric substrates having different layer configurations from each other are shown. One of the piezoelectric substrates is a substrate including, for example, only 42° rotated Y-cut X-propagating LiTaO₃ (LT). This substrate is defined as a first piezoelectric substrate. The other piezoelectric substrate is a bonded substrate including a piezoelectric layer and a support substrate. This substrate is defined as a second piezoelectric substrate. Specifically, for example, the second piezoelectric substrate is a substrate in which a silicon substrate having a plane orientation of (100), a silicon oxide film, and a lithium tantalate layer are laminated in that order. Even when the plane orientation of the silicon substrate is another plane orientation such as (110) or (111), the profile of the reverse-velocity surface does not change.

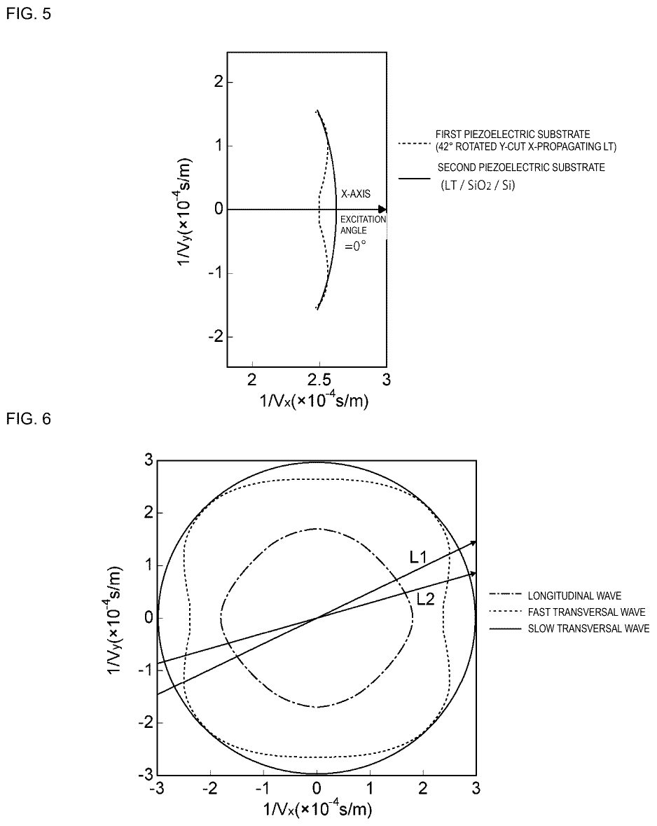

FIG. 5 is a diagram showing the reverse-velocity surfaces of acoustic waves propagating through the first piezoelectric substrate and the second piezoelectric substrate.

An X-axis shown in FIG. 5 corresponds to a result when the excitation direction of the acoustic wave is parallel to the propagation axis. That is, the X-axis corresponds to a result when the excitation angle θ_{C_prop} is about 0°. The reverse-velocity surfaces in the first and second piezoelectric substrates are both line-symmetric with respect to the X-axis as the axis of symmetry. The reverse-velocity surface in the first piezoelectric substrate has a concave shape. On the other hand, the reverse-velocity surface in the second piezoelectric substrate has a convex shape. Thus, it can be seen that the dependence of the acoustic wave propagating through the substrate on the excitation angle θ_{C_prop} differs depending on the configuration of the substrate. Moreover, when the mode of the acoustic wave differs, the dependence on the excitation angle θ_{C_prop} in the same substrate is different. This is shown by FIG. 6.

FIG. 6 is a diagram showing the reverse-velocity surfaces of a longitudinal wave, a fast transversal wave, and a slow transversal wave in the first piezoelectric substrate.

As shown in FIG. 6, the reverse-velocity surfaces of the longitudinal wave, the fast transversal wave, and the slow transversal wave, which are three kinds of acoustic wave modes, are different from each other. Portions passing through arrows L1 and L2 in FIG. 6 each correspond to an example of a result when the excitation angle θ_{C_prop} is not 0°. The interval between the reverse-velocity surfaces of the slow transversal wave and the fast transversal wave in the portion passing through the arrow L1 differs from the interval between the reverse-velocity surfaces of the slow transversal wave and the fast transversal wave in the portion passing through the arrow L2. Similarly, the interval between the reverse-velocity surfaces of the fast transversal wave and the longitudinal wave in the portion passing through the arrow L1 differs from the interval between the reverse-velocity surfaces of the fast transversal wave and the longitudinal wave in the portion passing through the arrow L2. That is, in the intersection region, the intervals between the reverse-velocity surfaces of different modes differ between portions having different excitation angles θ_{C_prop} from each other. This also applies to the relationship between the main mode used in the acoustic wave device and an unwanted wave.

In this case, in the acoustic wave device 1 of the present example embodiment, the resonant frequencies or the anti-resonant frequencies of the main mode are made substantially coincident with each other throughout the entire or substantially the entire intersection region J. Therefore, the frequencies of the unwanted wave are different from each other between portions having different excitation angles θ_{C_prop} from each other. Thus, unwanted waves outside the pass band are dispersed. Accordingly, the unwanted waves outside the pass band can be further reduced or prevented. In the present specification, the term “outside the pass band” or “out-of-band” in the acoustic wave device refers to the lower frequency side relative to the resonant frequency and the higher frequency side relative to the anti-resonant frequency.

In the present example embodiment, the main mode is favorably excited because the resonant frequencies or the anti-resonant frequencies in the intersection region substantially coincide with each other. Thus, the resonance characteristic can be more reliably made favorable.

As described above, the phase velocity corresponds to the inverse number of the reverse-velocity surface. Thus, the relationship between the excitation angle θ_{C_prop} and the phase velocity is the same or substantially the same as the reverse-velocity surface in the XY-plane of the piezoelectric substrate like those shown in FIG. 6. That is, it can be said that the function representing the bent shape of the electrode finger is determined by the shape of the reverse-velocity surface in the XY-plane of the piezoelectric substrate. The phase velocity of the acoustic wave has dependence on the excitation angle θ_{C_prop}.

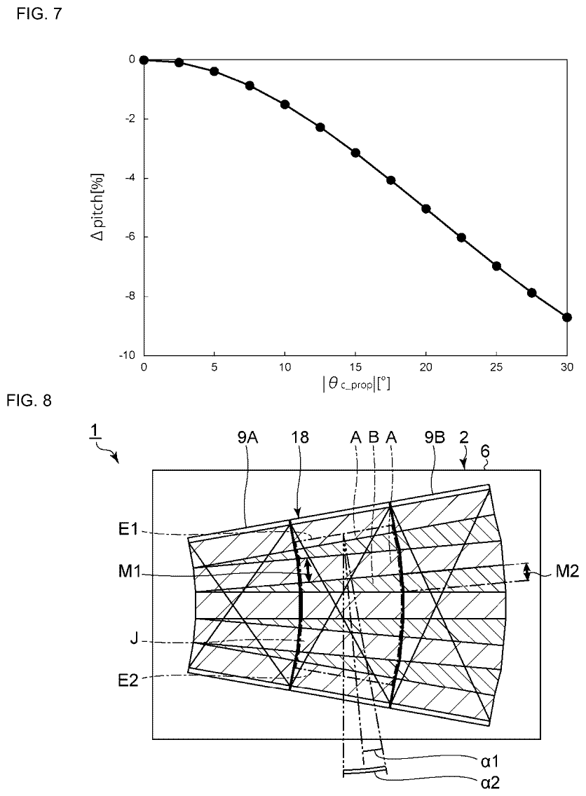

In the present example embodiment shown in FIG. 1, the electrode finger pitch, which affects the frequency, is varied in accordance with the excitation angle θ_{C_prop}, such that the frequencies of the acoustic wave excited at the respective excitation angles θ_{C_prop} are made substantially coincident with each other. The electrode finger pitch is the distance between the centers of the first electrode finger 16 and the second electrode finger 17 adjacent to each other. In portions where the excitation angle θ_{C_prop} is the same or substantially the same, the electrode finger pitch is constant. A relationship between the excitation angle θ_{C_prop} and the electrode finger pitch in the present example embodiment is shown in FIG. 7.

Here, the electrode finger pitch in a portion where the excitation angle θ_{C_prop} is about 0° is denoted as p0, and the electrode finger pitch in any portion is denoted as p1, and {(p1−p0)/p0}×100 [%] is defined as a rate of change Δpitch [%] of the electrode finger pitch.

FIG. 7 is a diagram showing a relationship between the absolute value of the excitation angle |θ_{C_prop}| and the rate of change Δpitch of the electrode finger pitch in the IDT electrode in the first example embodiment.

As shown in FIG. 7, in the present example embodiment, Δpitch is about 0% in the portion where the excitation angle θ_{C_prop} is about 0° in the IDT electrode 18. Further, as the absolute value of the excitation angle |θ_{C_prop}| increases, Δpitch increases in the negative direction. That is, the greater the absolute value of the excitation angle |θ_{C_prop}| is, the narrower the electrode finger pitch is. Accordingly, the resonant frequencies or the anti-resonant frequencies substantially coincide with each other throughout the entire or substantially the entire intersection region J.

The relationship between the electrode finger pitch and the frequency of each mode differs depending on the reverse-velocity surface of the piezoelectric substrate. Thus, depending on the configuration of the piezoelectric substrate or the configuration on the piezoelectric substrate, there may be a case in which the resonant frequencies or the anti-resonant frequencies substantially coincide with each other throughout the entire or substantially the entire intersection region when the electrode finger pitch becomes wider as the absolute value of the excitation angle |θ_{C_prop}| increases. An example of this case includes an acoustic wave device in which an IDT electrode disposed on a substrate including only −4° rotated Y-cut X-propagating LiNbO₃ is embedded in a thick SiO₂ film. Alternatively, in the portion where the excitation angle θ_{C_prop} is about 0°, the value of the electrode finger pitch is not necessarily the maximum or the minimum.

In example embodiments of the present invention, the resonant frequencies or the anti-resonant frequencies are not necessarily required to substantially coincide with each other throughout the entire intersection region. However, it is preferable that the resonant frequencies or the anti-resonant frequencies substantially coincide with each other in at least a portion of the intersection region. In this case, it is sufficient that the electrode finger pitch is made constant in portions where the excitation angle θ_{C_prop} is the same or substantially the same. Further, it is sufficient that the electrode finger pitch in portions where the excitation angle θ_{C_prop} is the same or substantially the same increase or decrease as the absolute value of the excitation angle |θ_{C_prop}| increases such that the resonant frequencies or the anti-resonant frequencies substantially coincide with each other in at least a portion of the intersection region.

It is more preferable that the resonant frequencies or the anti-resonant frequencies substantially coincide with each other throughout the entire or substantially the entire intersection region as in the present example embodiment. In this case, for example, it is sufficient that the electrode finger pitch in portions where the excitation angle θ_{C_prop} is the same or substantially the same increase or decrease as the absolute value of the excitation angle |θ_{C_prop}| increases such that the resonant frequencies or the anti-resonant frequencies substantially coincide with each other throughout the entire or substantially the entire intersection region. An example of this is as shown in FIG. 7.

The configuration of the present example embodiment is described in more detail below.

As shown in FIG. 1, the intersection region J of the IDT electrode 18 has a line-symmetric shape when the direction in which the propagation axis extends is regarded as the axis of symmetry. The first envelope E1 and the second envelope E2 extend obliquely with respect to the propagation axis. In the present example embodiment, the first envelope E1 and the second envelope E2 are linear.

As shown in FIG. 3, the IDT electrode 18 includes a plurality of first offset electrodes 12. One end of each of the first offset electrodes 12 is connected to the first busbar 14. The first electrode fingers 16 and the first offset electrodes 12 are alternately arranged. Each of the first offset electrodes 12 includes a base end portion and a tip portion. The base end portion of the first offset electrode 12 is a portion connected to the first busbar 14. The tip portion of the first offset electrode 12 and the tip portion of the second electrode finger 17 are opposite to each other with a gap therebetween.

The shapes of the first offset electrodes 12 in plan view are linear shapes. Specifically, as shown in FIG. 4, in the present example embodiment, one first outer parallel region C1 is located between the intersection region J and the first busbar 14. More specifically, the first outer parallel region C1 is a region in which the first electrode fingers 16 and the first offset electrodes 12 extend in parallel. All of the first offset electrodes 12 are located within the one first outer parallel region C1.

The parallel region A located closest to the first envelope E1 is in contact with the first outer parallel region C1. The plurality of first electrode fingers 16 are not bent at the boundary between this parallel region A and this first outer parallel region C1.

It is sufficient that at least one first electrode finger 16 and at least one first offset electrode 12 are located in the first outer parallel region C1. The IDT electrode 18 may include a plurality of first outer parallel regions C1. Alternatively, the IDT electrode 18 is not required to include the first outer parallel region C1.

Although not shown, the IDT electrode 18 includes a plurality of second offset electrodes. One end of each of the second offset electrodes is connected to the second busbar 15 shown in FIG. 1. The second electrode fingers 17 shown in FIG. 3 and the second offset electrodes are alternately arranged. Each of the second offset electrodes includes a base end portion and a tip portion. The base end portion of the second offset electrode is a portion connected to the second busbar 15. The tip portion of the second offset electrode and the tip portion of the first electrode finger 16 are opposite to each other with a gap therebetween.

The shapes of the second offset electrodes in plan view are linear shapes. Specifically, as shown in FIG. 4, in the present example embodiment, one second outer parallel region C2 is located between the intersection region J and the second busbar 15. More specifically, the second outer parallel region C2 is a region in which the second electrode fingers 17 and the second offset electrodes extend in parallel. All of the second offset electrodes are located within the one second outer parallel region C2.

The parallel region A located closest to the second envelope E2 is in contact with the second outer parallel region C2. The plurality of second electrode fingers 17 are not bent at the boundary between this parallel region A and this second outer parallel region C2.

It is sufficient that at least one second electrode finger 17 and at least one second offset electrode are located in the second outer parallel region C2. The IDT electrode 18 may include a plurality of second outer parallel regions C2. Alternatively, the IDT electrode 18 is not required to include the second outer parallel region C2.

However, the plurality of first offset electrodes 12 and the plurality of second offset electrodes are not necessarily required to be provided. Hereinafter, the first offset electrode 12 and the second offset electrode are sometimes referred to simply as offset electrode.

As shown in FIG. 1, a pair of reflectors 9A and 9B are disposed on the piezoelectric layer 6. The reflectors 9A and 9B are opposite to each other with the IDT electrode 18 interposed therebetween in the direction in which the electrode fingers of the IDT electrode 18 are arranged. The reflector 9A includes a pair of reflector busbars 9a and 9b. The reflector busbars 9a and 9b are opposite to each other. As shown in FIG. 2, the reflector 9A includes a plurality of reflector electrode fingers 9c. One end of each of the reflector electrode fingers 9c is connected to the reflector busbar 9a. The other end of each of the reflector electrode fingers 9c is connected to the reflector busbar 9b.

As shown in FIG. 3, the shapes of the plurality of reflector electrode fingers 9c in plan view are shapes bent at a plurality of nodes, similarly to each electrode finger of the IDT electrode 18. Hereinafter, a region obtained by extending the parallel region A in the direction in which this parallel region A extends is defined as an extension parallel region Ax, and a region obtained by extending the non-parallel region B in the direction in which this non-parallel region B extends is defined as an extension non-parallel region Bx. As shown in FIG. 4, one parallel region A is interposed between a pair of extension parallel regions Ax on the reflector 9A side and the reflector 9B side. Similarly, one non-parallel region B is interposed between a pair of extension non-parallel regions Bx.

Respective portions of each of the plurality of reflector electrode fingers 9c of the reflector 9A are included in a plurality of extension parallel regions Ax and a plurality of extension non-parallel regions Bx. In the extension parallel regions Ax, the directions in which the plurality of reflector electrode fingers 9c extend are parallel to each other. On the other hand, in the extension non-parallel regions Bx, the directions in which the plurality of reflector electrode fingers 9c extend intersect each other. The reflector electrode fingers 9c linearly extend in the extension parallel regions Ax and the extension non-parallel regions Bx, and are bent at the boundaries between the extension parallel region Ax and the extension non-parallel region Bx.

Similarly, the reflector 9B includes a pair of reflector busbars 9d and 9e. As shown in FIG. 2, the reflector 9B includes a plurality of reflector electrode fingers 9f. As shown in FIG. 4, each of the plurality of reflector electrode fingers 9f is included in a plurality of extension parallel regions Ax and a plurality of extension non-parallel regions Bx. The reflector electrode fingers 9f linearly extend in the extension parallel regions Ax and the extension non-parallel regions Bx, and are bent at the boundaries between the extension parallel region Ax and the extension non-parallel region Bx.

Examples of materials of the respective components in the acoustic wave device 1 are shown below.

As a material of the support substrate 4 shown in FIG. 2, for example, the following materials can also be used: a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiALON, a dielectric such as aluminum oxide, silicon oxynitride, diamond-like carbon (DLC), or diamond, a semiconductor such as silicon, or a material including the above material as a main component. The above spinel includes an aluminum compound including oxygen and one or more of from Mg, Fe, Zn, Mn, or the like. Examples of the above spinel include MgAl₂O₄, FeAl₂O₄, ZnAl₂O₄, or MnAl₂O₄. It is preferable that high-resistivity silicon is used for the support substrate 4. It is preferable that the volume resistivity of the material of the support substrate 4 is, for example, about 1000 Ω·cm or more. In the present example embodiment, high-resistivity silicon is used as the material of the support substrate 4, for example.

The first layer 5a of the intermediate layer 5 is a high acoustic velocity film. The high acoustic velocity film is a film having a relatively high acoustic velocity. Specifically, the acoustic velocity of a bulk wave propagating through the high acoustic velocity film is higher than the acoustic velocity of an acoustic wave propagating through the piezoelectric layer 6. As a material of the first layer 5a, which is the high acoustic velocity film, for example, the following materials can be used: a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiALON, a dielectric such as aluminum oxide, silicon oxynitride, diamond-like carbon (DLC), or diamond, a semiconductor such as silicon, or a material including the above material as a main component. The above spinel includes an aluminum compound including oxygen and one or more of Mg, Fe, Zn, Mn, or the like. Examples of the above spinel include MgAl₂O₄, FeAl₂O₄, ZnAl₂O₄, or MnAl₂O₄. In the present example embodiment, silicon nitride is used as the material of the first layer 5a, for example.

The second layer 5b of the intermediate layer 5 is a low acoustic velocity film. The low acoustic velocity film is a film having a relatively low acoustic velocity. Specifically, the acoustic velocity of a bulk wave propagating through the low acoustic velocity film is lower than the acoustic velocity of a bulk wave propagating through the piezoelectric layer 6. As a material of the second layer 5b, which is the low acoustic velocity film, for example, the following materials can be used: a dielectric such as glass, silicon oxide, silicon oxynitride, lithium oxide, tantalum oxide, or a compound obtained by adding fluorine, carbon, or boron to silicon oxide, or a material including the above material as a main component. In the present example embodiment, silicon oxide is used as the material of the second layer 5b, for example.

As a material of the piezoelectric layer 6 shown in FIG. 2, for example, lithium tantalate, lithium niobate, zinc oxide, aluminum nitride, quartz, lead zirconate titanate (PZT), or the like can be used. It is preferable that lithium tantalate or lithium niobate is used as the material of the piezoelectric layer 6. In the present example embodiment, lithium tantalate is used as the material of the piezoelectric layer 6, for example.

In the present example embodiment, in the piezoelectric substrate 2, the first layer 5a as the high acoustic velocity film, the second layer 5b as the low acoustic velocity film, and the piezoelectric layer 6 are laminated in that order. This allows energy of the acoustic wave to be effectively confined to the piezoelectric layer 6 side.

As a material of the IDT electrode 18, the reflector 9A, and the reflector 9B, for example, one or more of Ti, Mo, Ru, W, Al, Pt, Ir, Cu, Cr, or Sc may be used. The IDT electrode 18 and each reflector may include a single-layer metal film or a multilayer metal film. In the present example embodiment, for example, Al is used as the material of the IDT electrode 18, the reflector 9A, and the reflector 9B.

In the present specification, the term “main component” refers to a component having a proportion exceeding 50% by weight. The material of the above main component may be present in any of a single-crystal state, a polycrystalline state, and an amorphous state or in a state in which these states are mixed.

An example of design parameters of the acoustic wave device 1 is shown below. Here, a dimension of the offset electrode along a direction connecting the base end portion and the tip portion thereof is defined as a length of the offset electrode. A dimension of the gap between the tip portion of the electrode finger and the tip portion of the offset electrode along the direction in which this electrode finger and this offset electrode are opposite to each other is defined as a gap length. In the present example embodiment, the gap length of the gap between the tip portion of the second electrode finger 17 and the tip portion of the first offset electrode 12 is the same as the gap length of the gap between the tip portion of the first electrode finger 16 and the tip portion of the second offset electrode. A wavelength defined by the electrode finger pitch of the IDT electrode 18 is denoted as λ. When the electrode finger pitch of the IDT electrode 18 is denoted as p, λ=2p.
Support substrate 4: material . . . Si, plane orientation . . . (111), ψ in the Euler angles (φ, θ, ψ) . . . about 73°
First layer 5a: material . . . SiN, thickness . . . about 0.15 λ
Second layer 5b: material . . . SiO₂, thickness . . . about 0.15 λ
Piezoelectric layer 6: material . . . about 55° rotated Y-cut X-propagating LiTaO₃, thickness . . . about 0.2 λ
IDT electrode 18: material . . . Al, thickness . . . about 0.05 λ
Wavelength λ: about 2 μm in a portion where the excitation angle θ_{C_prop} is about 0°
Number of pairs of electrode fingers of the IDT electrode 18: 100 pairs
Duty ratio: about 0.5
Gap length: about 0.135 λ
Length of offset electrode: about 3.5 λ
Reflector 9A and reflector 9B: number of pairs of reflector electrode fingers . . . 20 pairs

Preferred configurations of example embodiments of the present invention are shown below.

It is preferable that the non-parallel region B connect adjacent parallel regions A to each other. This can more reliably make the excitation angle θ_{C_prop} different between the adjacent parallel regions A. Accordingly, out-of-band unwanted waves can be more reliably reduced or prevented.

It is preferable that the intersection region J includes two or more parallel regions A and two or more non-parallel regions B, and that the parallel region A and the non-parallel region B be alternately disposed two or more times. It is more preferable that the intersection region J includes three or more parallel regions A and three or more non-parallel regions B, and that the parallel region A and the non-parallel region B be alternately disposed three or more times. With this configuration, the range of the excitation angle θ_{C_prop} in the intersection region J can be widened. This can effectively disperse out-of-band unwanted waves, and effectively reduce or prevent the out-of-band unwanted waves.

In example embodiments of the present invention, it is sufficient that the parallel region A and the non-parallel region B are alternately disposed in at least a portion of the intersection region J. However, it is preferable that the parallel region A and the non-parallel region B are alternately disposed throughout the entire or substantially the entire intersection region J. With this configuration, out-of-band unwanted waves can be more reliably dispersed and more reliably reduced or prevented.

It is preferable that the shapes of all of the first electrode fingers 16 and all of the second electrode fingers 17 in the IDT electrodes 18 in plan view are different from each other. With this configuration, the excitation angles θ_{C_prop} can be made different from each other among the plurality of parallel regions A.

Specifically, in the first example embodiment, in each non-parallel region B, the shapes of all of the first electrode fingers 16 and all of the second electrode fingers 17 in plan view are different from each other. More specifically, in the non-parallel region B, the plurality of electrode fingers do not extend in parallel with each other, and the dimensions of the plurality of electrode fingers along the electrode finger extension direction are different from each other. On the other hand, in each parallel region A, the shapes of all of the first electrode fingers 16 and all of the second electrode fingers 17 in plan view are the same or substantially the same. Further, in each electrode finger, portions located in the adjacent parallel regions A are connected to each other by a portion located in the non-parallel region B.

Accordingly, the shapes of all of the first electrode fingers 16 and all of the second electrode fingers 17 in plan view are different from each other. In this case, the excitation angles θ_{C_prop} are different from each other among the plurality of parallel regions A. Thus, out-of-band unwanted waves can be more reliably reduced or prevented.

It is preferable that the shape of the outer peripheral edge of at least one parallel region A in plan view is rectangular or substantially rectangular. Hereinafter, when the term “outer peripheral edge” is simply described unless otherwise specified, this term refers to the outer peripheral edge in plan view. The dimension along the electrode finger extension direction regarding the parallel region A having a rectangular or substantially rectangular outer peripheral edge is uniform. Thus, the resonance characteristic can be more reliably made favorable throughout the whole of this parallel region A. In the first example embodiment, as shown in FIG. 4, the shapes of the outer peripheral edges of all the parallel regions A are rectangular or substantially rectangular.

Alternatively, it is preferable that the shape of the outer peripheral edge of at least one parallel region A in plan view is trapezoidal or substantially trapezoidal. In this case, it is easier to make the occupancy ratio of the parallel region A in the intersection region J higher than that of the non-parallel region B. Further, the resonance characteristic becomes more favorable when the occupancy ratio of the parallel region A in the intersection region J is higher. Thus, when a trapezoidal or substantially trapezoidal shape is used as the shape of the outer peripheral edge of the parallel region A, the resonance characteristic of the acoustic wave device can be more reliably made favorable.

Here, the parallel region A and the non-parallel region B adjacent thereto are defined as one set of the parallel region A and the non-parallel region B. As shown in FIG. 8, in one set of the parallel region A and the non-parallel region B, the minimum value of the dimension of the parallel region A along the electrode finger extension direction is defined as M1, and the maximum value of the dimension of the non-parallel region B along the electrode finger extension direction in the parallel region A is defined as M2. It is preferable that M1>M2 be satisfied in at least one set of the parallel region A and the non-parallel region B. It is more preferable that M1>M2 be satisfied in a plurality of sets of the parallel regions A and the non-parallel regions B, and it is still more preferable that M1>M2 be satisfied in all sets of the parallel regions A and the non-parallel regions B.

The dimension M2 is defined for each set of the parallel region A and the non-parallel region B in which the dimensions M1 and M2 are to be compared. For example, in the first example embodiment, the number of parallel regions A adjacent to one non-parallel region B is two. When the dimensions M1 and M2 are compared in one of the parallel regions A and the non-parallel region B, the electrode finger extension direction is the electrode finger extension direction in this one parallel region A. When the dimensions M1 and M2 are compared in the other parallel region A and the non-parallel region B, the electrode finger extension direction is the electrode finger extension direction in the other parallel region A.

The resonance characteristic becomes more favorable when the occupancy ratio of the parallel region A in the intersection region J is higher. Further, by setting M1>M2 in at least one set of the parallel region A and the non-parallel region B, increasing the occupancy ratio of the parallel region A in the intersection region J is facilitated. By setting M1>M2 in all sets of the parallel regions A and the non-parallel regions B, the occupancy ratio of the parallel region A in the intersection region J can be more reliably increased. Thus, the resonance characteristic can be more reliably made favorable.

The maximum value among the dimensions M1 of all of the parallel regions A is, for example, preferably about 1.5 times or less the minimum value among the dimensions M1 of all the parallel regions A, more preferably about 1.2 times or less the minimum value, and still more preferably about 1.05 times or less the minimum value. In this case, it is easier to evenly dispose the parallel regions A in the intersection region J.

In the first example embodiment, the electrode finger pitch varies in accordance with the excitation angle θ_{C_prop}. That is, the electrode finger pitch is the same or substantially the same in the same parallel region A. On the other hand, the electrode finger pitches are different from each other between the parallel regions A having different excitation angles θ_{C_prop} from each other. In other words, the electrode finger pitches are different from each other between the parallel regions A having different electrode finger extension directions from each other. Further, in each parallel region A, the electrode finger pitch in accordance with the excitation angle θ_{C_prop} is set. Accordingly, the resonant frequencies or the anti-resonant frequencies substantially coincide with each other throughout the entire or substantially the entire intersection region J. However, a parameter other than the electrode finger pitch may be varied in accordance with the excitation angle θ_{C_prop} such that the resonant frequencies or the anti-resonant frequencies substantially coincide with each other in at least a portion of the intersection region J.

Specifically, it is preferable that, for example, at least one of the duty ratio, the electrode finger pitch, or the thickness of the plurality of first electrode fingers 16 and the plurality of second electrode fingers 17 vary in accordance with the excitation angle θ_{C_prop}. It is preferable that at least one of these parameters vary in accordance with the excitation angle θ_{C_prop} such that the resonant frequencies or the anti-resonant frequencies substantially coincide with each other in at least part of the intersection region J. It is more preferable that at least one of these parameters vary in accordance with the excitation angle θ_{C_prop} such that the resonant frequencies or the anti-resonant frequencies substantially coincide with each other throughout the entire intersection region J. With this configuration, the resonance characteristic can be more reliably made favorable.

Alternatively, when the thickness of the intermediate layer 5 in the piezoelectric substrate 2, or the like, affects the frequency, the relevant parameter may be varied in accordance with the excitation angle θ_{C_prop} in the intersection region J. When a dielectric film is disposed on the piezoelectric substrate 2 so as to cover the IDT electrode 18, the thickness of the dielectric film may be varied in accordance with the excitation angle θ_{C_prop} in the intersection region J. A plurality of parameters among the above parameters of the IDT electrode 18 or parameters other than those of the IDT electrode 18 may be varied in accordance with the excitation angle θ_{C_prop} in the intersection region J. Also in these cases, the resonant frequencies or the anti-resonant frequencies can be made substantially coincident with each other in at least part of the intersection region J or throughout the entire intersection region J.

When at least one of the above parameters is varied in accordance with the excitation angle θ_{C_prop}, specifically, this parameter is constant in the same parallel region A. On the other hand, values of this parameter are different from each other between the parallel regions A having different excitation angles θ_{C_prop} from each other. In other words, at least one of the above parameters is constant in the same parallel region A, and values of this parameter are different from each other between the parallel regions A having different electrode finger extension directions from each other.

As shown in FIG. 8, in the present example embodiment, the intersection region J includes three or more parallel regions A. In three parallel regions A consecutive from the first envelope E1 side toward the second envelope E2 side, an angle between the electrode finger extension direction in the parallel region A located closest to the first envelope E1 and the electrode finger extension direction in the parallel region A adjacent to this parallel region A is defined as α1. In the above three parallel regions A, an angle between the electrode finger extension direction in the parallel region A located closest to the first envelope E1 and the electrode finger extension direction in the parallel region A located closest to the second envelope E2 is defined as α2. In this case, it is preferable that α1<α2 is satisfied.

The angle α1 indicated in FIG. 8 is based on the electrode finger extension direction in the parallel region A located closest to the first envelope E1 among all the parallel regions A. However, the configuration is not limited thereto, and it is preferable that the plurality of parallel regions A include three parallel regions A in which the relationship of α1<α2 is satisfied. This makes it easier to treat the parameter of the IDT electrode 18 or the like as the parameter in accordance with the excitation angle θ_{C_prop}.

In the following, in first to fourth modifications of the first example embodiment, examples in which a parameter other than the electrode finger pitch is varied in accordance with the excitation angle θ_{C_prop} are shown. Also in the first to fourth modifications, similarly to the first example embodiment, the resonance characteristic can be more reliably made favorable, and out-of-band unwanted waves can be effectively reduced or prevented.

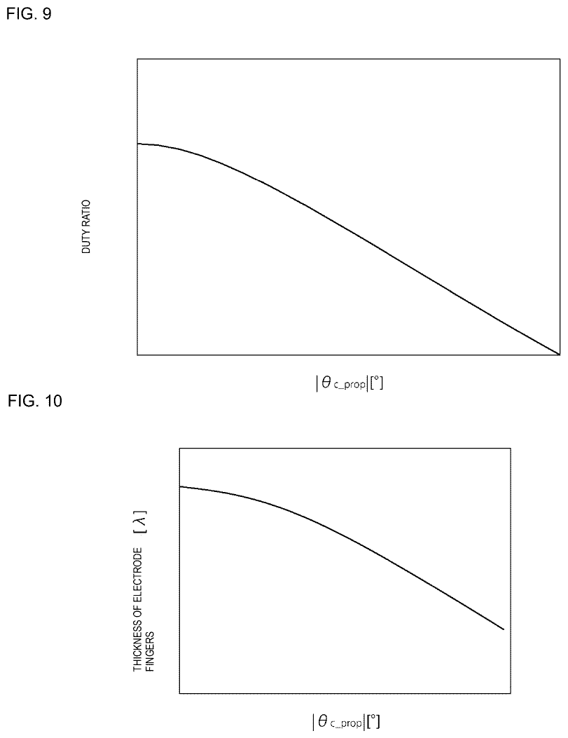

FIG. 9 is a diagram showing a relationship between the absolute value of the excitation angle |θ_{C_prop}| and the duty ratio in the IDT electrode in the first modification of the first example embodiment.

In the first modification, the duty ratio is constant in portions where the excitation angle θ_{C_prop} is the same or substantially the same in the plurality of first electrode fingers and the plurality of second electrode fingers. That is, the duty ratio is constant in the same parallel region. When the excitation angle θ_{C_prop} is about 0°, the duty ratio is set to the maximum value. Further, the duty ratio in portions where the excitation angle θ_{C_prop} is the same or substantially the same decreases as the absolute value of the excitation angle |θ_{C_prop}| increases such that the resonant frequencies or the anti-resonant frequencies substantially coincide with each other throughout the entire intersection region.

The relationship between the duty ratio and the frequency of each mode differs depending on the reverse-velocity surface of the piezoelectric substrate. Thus, depending on the configuration of the piezoelectric substrate or the configuration on the piezoelectric substrate, there may be a case in which the resonant frequencies or the anti-resonant frequencies substantially coincide with each other throughout the entire or substantially the entire intersection region when the duty ratio becomes higher as the absolute value of the excitation angle |θ_{C_prop}| increases. An example of this case includes an acoustic wave device in which an IDT electrode disposed on a substrate including only −4° rotated Y-cut X-propagating LiNbO₃ is embedded in a thick SiO₂ film. Alternatively, in a portion where the excitation angle θ_{C_prop} is about 0°, the duty ratio is not necessarily the maximum or the minimum.

The configuration of the present modification is an example of the configuration in which the duty ratio varies in accordance with the excitation angle θ_{C_prop}. For example, it is sufficient that the duty ratio in portions where the excitation angle θ_{C_prop} is the same or substantially the same increase or decrease as the absolute value of the excitation angle |θ_{C_prop}| increases such that the resonant frequencies or the anti-resonant frequencies substantially coincide with each other in at least part of the intersection region. Also in this case, the resonance characteristic can be more reliably made favorable, and out-of-band unwanted waves can be effectively reduced or prevented.

FIG. 10 is a diagram showing a relationship between the absolute value of the excitation angle |θ_{C_prop}| and the thickness of the electrode fingers in the IDT electrode in the second modification of the first example embodiment.

In the second modification, the thickness of the plurality of first electrode fingers and the plurality of second electrode fingers is constant in portions where the excitation angle θ_{C_prop} is the same or substantially the same. When the excitation angle θ_{C_prop} is about 0°, the above thickness is the greatest. Further, the thickness of the electrode fingers decreases as the absolute value of the excitation angle |θ_{C_prop}| increases such that the resonant frequencies or the anti-resonant frequencies substantially coincide with each other throughout the entire intersection region.

The relationship between the thickness of the first electrode fingers and the second electrode fingers and the frequency of each mode differs depending on the reverse-velocity surface of the piezoelectric substrate. Thus, depending on the configuration of the piezoelectric substrate or the configuration on the piezoelectric substrate, there may be a case in which the resonant frequencies or the anti-resonant frequencies substantially coincide with each other throughout the entire intersection region when the thickness of each electrode finger becomes larger as the absolute value of the excitation angle |θ_{C_prop}| increases. An example of this case includes an acoustic wave device in which an IDT electrode disposed on a substrate including only −4° rotated Y-cut X-propagating LiNbO₃ is embedded in a thick SiO₂ film. Alternatively, in a portion where the excitation angle θ_{C_prop} is about 0°, the value of the thickness of the first electrode fingers and the second electrode fingers is not necessarily the maximum or the minimum.

The configuration of the present modification is an example of the configuration in which the thickness of the first electrode fingers and the second electrode fingers varies in accordance with the excitation angle θ_{C_prop}. For example, it is sufficient that the thickness of the electrode fingers increase or decrease as the absolute value of the excitation angle |θ_{C_prop}| increases such that the resonant frequencies or the anti-resonant frequencies substantially coincide with each other in at least part of the intersection region. Also in this case, the resonance characteristic can be more reliably made favorable, and out-of-band unwanted waves can be effectively reduced or prevented.

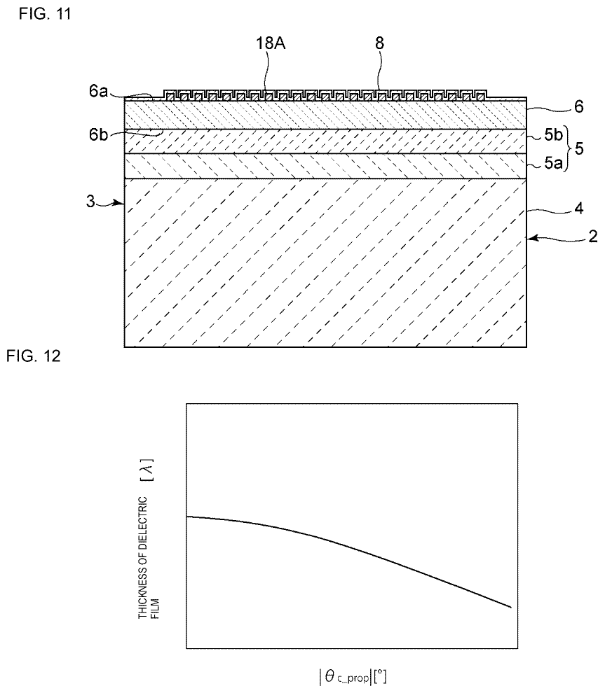

FIG. 11 is a schematic elevational cross-sectional view of an acoustic wave device according to the third modification of the first example embodiment. FIG. 11 shows a section corresponding to the portion shown in FIG. 2. The same applies to the schematic elevational cross-sectional views other than FIG. 11.

In the third modification, a dielectric film 8 is disposed on the piezoelectric layer 6 so as to cover an IDT electrode 18A. The acoustic velocity of a transversal wave propagating through the dielectric film 8 in the present modification is lower than the acoustic velocity of the main mode propagating through the dielectric film 8. The thickness of a portion of the dielectric film 8 located on a portion where the excitation angle θ_{C_prop} is the same or substantially the same in the portion covering the intersection region in the dielectric film 8 is constant. Further, the thickness of the dielectric film 8 differs depending on the excitation angle θ_{C_prop}. In other words, the thickness of the dielectric film 8 is constant in the same or substantially the same parallel region A, and values of the thickness are different from each other between the parallel regions A having different electrode finger extension directions from each other.

FIG. 12 is a diagram showing a relationship between the absolute value of the excitation angle |θ_{C_prop}| and the thickness of the portion covering the intersection region in the dielectric film in the third modification of the first example embodiment.

In the present modification, the thickness of the dielectric film 8 varies such that the resonant frequencies or the anti-resonant frequencies substantially coincide with each other throughout the entire or substantially the entire intersection region. Specifically, the thickness of the portion covering the intersection region in the dielectric film 8 decreases as the absolute value of the excitation angle |θ_{C_prop}| increases.

In a description of the fourth modification of the first example embodiment, FIG. 11 is referred to. The fourth modification is different from the third modification in the material used for the dielectric film 8 and in the manner of variation in thickness. Specifically, in the fourth modification, the acoustic velocity of a transversal wave propagating through the dielectric film 8 is higher than the acoustic velocity of the main mode propagating through the dielectric film 8.

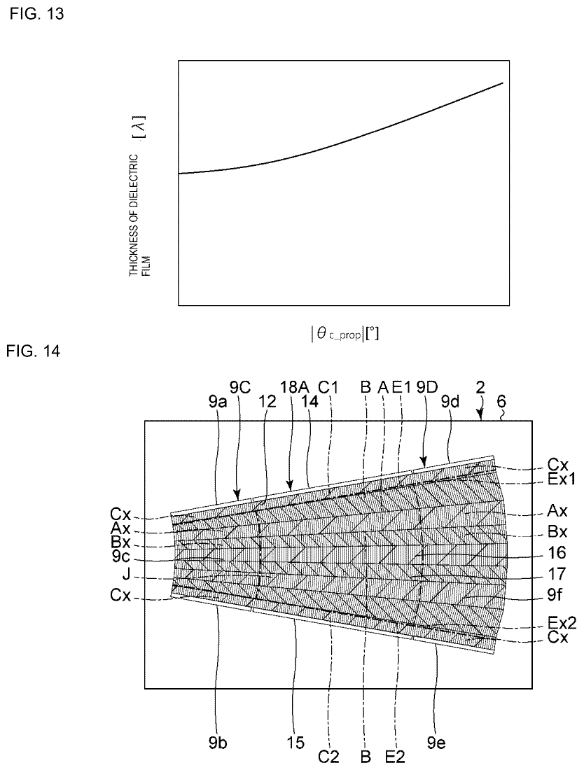

FIG. 13 is a diagram showing a relationship between the absolute value of the excitation angle |θ_{C_prop}| and the thickness of the portion covering the intersection region in the dielectric film in the fourth modification of the first example embodiment.

In the fourth modification, similarly to the third modification, the thickness of the dielectric film 8 varies such that the resonant frequencies or the anti-resonant frequencies substantially coincide with each other throughout the entire or substantially the entire intersection region. In the present modification, specifically, the thickness of the portion covering the intersection region in the dielectric film 8 increases as the absolute value of the excitation angle |θ_{C_prop}| increases.

Depending on the configuration of the piezoelectric substrate or the like, the value of the thickness of a portion of the dielectric film located in a portion where the excitation angle θ_{C_prop} is about 0° is not necessarily the maximum or the minimum.

The configurations of the third and fourth modifications are each an example of the configuration in which the thickness of the dielectric film 8 varies in accordance with the excitation angle θ_{C_prop}. For example, it is sufficient that the thickness of the portion covering the intersection region in the dielectric film 8 increases or decreases as the absolute value of the excitation angle |θ_{C_prop}| increases such that the resonant frequencies or the anti-resonant frequencies substantially coincide with each other in at least part of the intersection region. Also in this case, the resonance characteristic can be more reliably made favorable, and out-of-band unwanted waves can be effectively reduced or prevented.

In the first example embodiment and the first to fourth modifications thereof, the advantageous effect of effectively reducing or preventing out-of-band unwanted waves can be obtained even when a deviation of approximately ±1° to approximately ±2° occurs in the excitation angle θ_{C_prop} in the relationship between each parameter and the excitation angle θ_{C_prop}.

As shown in FIG. 3, it is preferable that the IDT electrode 18 includes the plurality of first offset electrodes 12. The main mode excited in the intersection region J tends to leak toward the first busbar 14 side. In contrast, in the first example embodiment, the leaked main mode can be reflected toward the intersection region J side by the first offset electrodes 12. Accordingly, the leakage of the main mode from the intersection region J toward the first busbar 14 side can be reduced or prevented.

Similarly, it is preferable that the IDT electrode 18 includes the plurality of second offset electrodes. As described above, the second offset electrodes are electrodes including the base end portions connected to the second busbar 15 and the tip portions opposite to the tip portions of the first electrode fingers 16. With this configuration, the leakage of the main mode from the intersection region J toward the second busbar 15 side can be reduced or prevented.

In the first example embodiment, the shapes of the first offset electrodes 12 in plan view are linear shapes. The first offset electrodes 12 are not bent. In this case, the distance from the tip portion of the first offset electrode 12 to the first busbar 14 can be shortened. This can reduce the electrical resistance of the IDT electrode 18. Accordingly, when the acoustic wave device 1 is used in a filter device, an increase in insertion loss can be reduced or prevented.

Similarly, the shapes of the second offset electrodes in plan view are linear shapes. Each of the second offset electrodes is not bent. This can more reliably lower the electrical resistance of the IDT electrode 18, and more reliably reduce or prevent an increase in insertion loss when the acoustic wave device 1 is used in a filter device.

Hereinafter, the offset electrode and the electrode finger including the tip portions opposite to each other are referred to as a pair of offset electrode and electrode finger. It is preferable that, in at least one pair of the first offset electrode 12 and the second electrode finger 17, a linear portion including the tip portion of the first offset electrode 12 and a linear portion including the tip portion of the second electrode finger 17 extend in parallel. It is more preferable that, in a plurality of pairs of the first offset electrodes 12 and the second electrode fingers 17, linear portions including the tip portions of the first offset electrodes 12 and linear portions including the tip portions of the second electrode fingers 17 extend in parallel. With this configuration, the condition of the intersection region J in which the main mode is excited and the condition of the region in which the plurality of first offset electrodes 12 are disposed can be made at least closer to each other or can be made to coincide with each other. This makes it possible to effectively reflect the main mode toward the intersection region J side. Accordingly, the leakage of the main mode can be more reliably reduced or prevented.

Similarly, it is preferable that at least one pair of a linear portion including the tip portion in the second offset electrode and a linear portion including the tip portion in the first electrode finger 16 opposite to this second offset electrode extend in parallel. It is more preferable that a plurality of pairs of linear portions including the tip portions in the second offset electrodes and linear portions including the tip portions in the first electrode fingers 16 opposite to these second offset electrodes extend in parallel. With this configuration, the leakage of the main mode can be more reliably reduced or prevented.

As shown in FIG. 4, it is preferable that the plurality of reflector electrode fingers of the reflectors 9A and 9B each have a shape corresponding to the shape of the electrode finger in the intersection region J of the IDT electrode 18. Specifically, it is preferable that respective portions of each of the plurality of reflector electrode fingers of the reflectors 9A and 9B are included in the plurality of extension parallel regions Ax and the plurality of extension non-parallel regions Bx. In this case, in any parallel region A of the IDT electrode 18 and the extension parallel region Ax obtained by extending this parallel region A in the direction in which this parallel region A extends, the electrode finger extension direction and the direction in which the plurality of reflector electrode fingers extend are parallel to each other. Thus, the resonance characteristic of the acoustic wave device 1 can be more reliably made favorable.

Hereinafter, a region obtained by extending the first outer parallel region C1 in the direction in which the first outer parallel region C1 extends and a region obtained by extending the second outer parallel region C2 in the direction in which the second outer parallel region C2 extends are defined as extension outer parallel regions Cx. One first outer parallel region C1 is interposed between a pair of extension outer parallel regions Cx on the reflector 9A side and the reflector 9B side. Similarly, one second outer parallel region C2 is interposed between a pair of extension outer parallel regions Cx.

In the first example embodiment, a portion of each of the plurality of reflector electrode fingers 9c of the reflector 9A is included in one extension outer parallel region Cx. The reflector electrode fingers 9c linearly extend in the extension outer parallel region Cx. The extension outer parallel region Cx is adjacent to the extension parallel region Ax. The reflector electrode fingers 9c are not bent at the boundary between the extension outer parallel region Cx and the extension parallel region Ax.

Similarly, a portion of each of the plurality of reflector electrode fingers 9f of the reflector 9B is also included in one extension outer parallel region Cx. Also on the reflector 9B side, the extension outer parallel region Cx is adjacent to the extension parallel region Ax. The reflector electrode fingers 9f are not bent at the boundary between the extension outer parallel region Cx and the extension parallel region Ax.

One region is provided by coupling the parallel region A located closest to the first envelope E1, the respective extension parallel regions Ax located on both sides of this parallel region A, the first outer parallel region C1, and the respective extension outer parallel region Cx located on both sides of the first outer parallel region C1. The shape of the outer peripheral edge of this region is rectangular or substantially rectangular. The same applies to the second envelope E2 side.

In the first example embodiment, the extension parallel regions Ax that are located on the reflector 9A side and adjacent to each other are connected to each other at the reflector electrode finger 9c farthest from the IDT electrode 18. That is, the shape of the outer peripheral edge of each extension non-parallel region Bx located on the reflector 9A side is triangular or substantially triangular. Accordingly, it is easier to make the occupancy ratio of the parallel region A in the intersection region J of the IDT electrode 18 higher than that of the non-parallel region B. Thus, the resonance characteristic of the acoustic wave device 1 can be more reliably made favorable.

The shape of each reflector electrode finger in plan view may be a shape that does not correspond to the shape of the electrode finger in the intersection region J of the IDT electrode 18. Alternatively, for example, each reflector electrode finger is not required to overlap the offset electrodes when viewed in a normal direction to the direction in which the offset electrodes extend. However, it is preferable that each reflector electrode finger overlap the offset electrodes when viewed in a normal direction to the direction in which the offset electrodes extend and overlap the intersection region J when viewed in a normal direction to the electrode finger extension direction. In this case, the resonance characteristic can be more reliably made favorable.

As described above, the direction in which the propagation axis extends is parallel or substantially parallel to the dash-dot-dot line N shown in FIG. 1. In the IDT electrode 18, the first envelope E1 and the second envelope E2 extend obliquely with respect to the propagation axis. The first envelope E1 and the second envelope E2 may extend in parallel or substantially in parallel with the direction in which the propagation axis extends. However, it is preferable that at least one of the first envelope E1 or the second envelope E2 extend obliquely with respect to the propagation axis, and it is more preferable that both the first envelope E1 and the second envelope E2 extend obliquely with respect to the propagation axis. This can reduce or prevent a transverse mode. The transverse mode is an unwanted wave that occurs between the resonant frequency and the anti-resonant frequency.

In a case in which the duty ratio is varied, such as in the first modification of the first example embodiment, the width of each electrode finger is not necessarily required to vary continuously. The width of each electrode finger may vary discontinuously. In this case, for example, it is sufficient that each electrode finger has a configuration corresponding to a configuration in which a plurality of portions are connected, and that the widths of the connected portions are different from each other at a connection portion where different portions are connected to each other. In this case, it is sufficient that a line passing through the center of each electrode finger in a normal direction to the electrode finger extension direction is bent at the boundary between the parallel region A and the non-parallel region B. The same applies to each reflector electrode finger.

FIG. 14 is a schematic plan view of an acoustic wave device according to a second example embodiment of the present invention.

The present example embodiment is different from the first example embodiment in the shapes of the outer peripheral edges of the parallel region A, the extension parallel region Ax, the extension non-parallel region Bx, and the extension outer parallel region Cx. The present example embodiment is different from the first example embodiment also in that the extension parallel regions Ax that are located on the reflector 9C side and adjacent to each other are not connected to each other at a single point. The shapes of the reflector 9C and a reflector 9D are made to correspond to the shape of the IDT electrode 18A. Except for the above points, the acoustic wave device of the present example embodiment has the same or substantially the same configuration as the acoustic wave device 1 of the first example embodiment.

The shapes of the outer peripheral edges of the parallel region A located closest to the first envelope E1 and the parallel region A located closest to the second envelope E2 are triangular or substantially triangular. The shapes of the outer peripheral edges of the plurality of parallel regions A other than the parallel region A located closest to the first envelope E1 and the parallel region A located closest to the second envelope E2 are each trapezoidal or substantially trapezoidal. In the same parallel region A, the electrode finger located closer to the reflector 9D has a larger dimension along the electrode finger extension direction.

In the parallel region A whose outer peripheral edge has a trapezoidal or substantially trapezoidal shape, the upper base of this trapezoidal shape is included in the electrode finger located closest to the reflector 9C. The lower base of the above shape is included in the electrode finger located closest to the reflector 9D.

Also in the present example embodiment, the parallel region A and the non-parallel region B are alternately disposed, and the plurality of electrode fingers each linearly extend in the plurality of parallel regions A and the non-parallel region B, and are each bent at the boundaries between the parallel region A and the non-parallel region B. Accordingly, similarly to the first example embodiment, out-of-band unwanted waves can be effectively reduced or prevented in the acoustic wave device.

As shown in FIG. 14, the shape of the outer peripheral edge of each extension parallel region Ax is trapezoidal or substantially trapezoidal. One region is provided by coupling one parallel region A whose outer peripheral edge has a trapezoidal or substantially trapezoidal shape and the respective extension parallel regions Ax located on both sides of this parallel region A. The shape of the outer peripheral edge of this region is trapezoidal or substantially trapezoidal. The upper base of this trapezoidal or substantially trapezoidal shape is included in the reflector electrode finger farthest from the IDT electrode 18A in the reflector 9C. The lower base of the above shape is included in the reflector electrode finger farthest from the IDT electrode 18A in the reflector 9D.

One region is provided by coupling the parallel region A closest to the first envelope E1, the extension parallel region Ax located on the reflector 9D side of this parallel region A, the first outer parallel region C1, and the respective extension outer parallel regions Cx located on both sides of the first outer parallel region C1. The shape of the outer peripheral edge of this region is trapezoidal or substantially trapezoidal. The same applies to the second envelope E2 side.

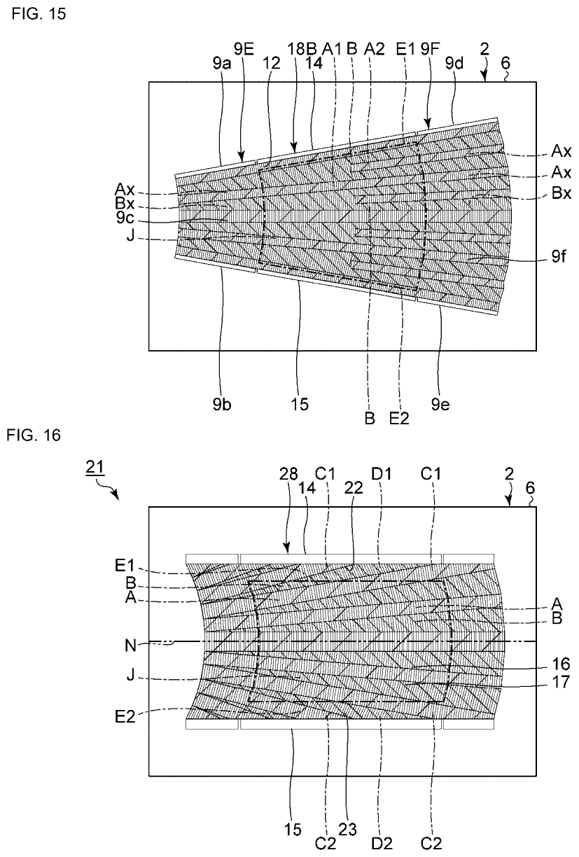

FIG. 15 is a schematic plan view of an acoustic wave device according to a third example embodiment of the present invention.

The present example embodiment is different from the first example embodiment in that a plurality of parallel regions include a first parallel region A1 including all of the first electrode fingers and all of the second electrode fingers and a second parallel region A2 including a plurality of first electrode fingers as a portion of all of the first electrode fingers and a plurality of second electrode fingers as a portion of all of the second electrode fingers. The present example embodiment is different from the first example embodiment also in that the extension parallel regions Ax that are located on the reflector 9E side and adjacent to each other are not connected to each other at a single point. The shapes of the reflector 9E and a reflector 9F are made to correspond to the shape of an IDT electrode 18B. Except for the above points, the acoustic wave device of the present example embodiment has the same or substantially the same configuration as the acoustic wave device 1 of the first example embodiment.

The IDT electrode 18B includes a plurality of electrode fingers a portion of which is included in the second parallel region A2 and a plurality of electrode fingers no portion of which is included in the second parallel region A2. In the present example embodiment, with one electrode finger being a boundary, a portion of a plurality of electrode fingers on the reflector 9F side including this electrode finger is included in the second parallel region A2. On the other hand, with the above one electrode finger being the boundary, no portion of a plurality of electrode fingers on the reflector 9E side that do not include this electrode finger is included in the second parallel region A2. In the present example embodiment, the numbers of electrode fingers a portion of which is included in the respective second parallel regions A2 are the same. However, the numbers of electrode fingers that are partially included may be different from each other among the second parallel regions A2.

In a portion of the intersection region J, the first parallel region A1 and the non-parallel region B are alternately disposed. In the other portion of the intersection region J, the first parallel region A1, the non-parallel region B, the second parallel region A2, the non-parallel region B, and the first parallel region A1 are disposed in that order. That is, also in the present example embodiment, the parallel region and the non-parallel region B are alternately disposed, and the plurality of electrode fingers each linearly extend in the plurality of parallel regions and the non-parallel region B, and are each bent at the boundaries between the parallel region and the non-parallel region B. Accordingly, similarly to the first example embodiment, out-of-band unwanted waves can be effectively reduced or prevented in the acoustic wave device.

In the present example embodiment, the electrode finger located closer to the reflector 9F has a larger total of the dimensions of the respective portions along the electrode finger extension direction. In this case, particularly when the shape of the outer peripheral edge of the parallel region is rectangular or substantially rectangular, the electrode finger located closer to the reflector 9F tends to have a higher occupancy ratio of the portion located in the non-parallel region B in the entire or substantially the entire electrode finger. In contrast, as shown in FIG. 15, the second parallel region A2 is located between the first parallel regions A1. This makes it possible to increase the occupancy ratio of the parallel region in the entire or substantially the entire electrode finger even in the electrode finger having a large total of the above dimensions. This can increase the occupancy ratio of the parallel region in the intersection region J. Accordingly, the resonance characteristic of the acoustic wave device can be more reliably made favorable.

In the present example embodiment, in any first parallel region A1 and a pair of extension parallel regions Ax located on both sides of this first parallel region A1, the electrode finger extension direction is parallel or substantially parallel to the direction in which the plurality of reflector electrode fingers of the pair of reflectors extend. On the other hand, the extension parallel region Ax obtained by extending any second parallel region A2 in the direction in which this second parallel region A2 extends is disposed only on the side of the reflector 9F of the reflectors 9E and 9F. Further, in any second parallel region A2 and the extension parallel region Ax obtained by extending this second parallel region A2 in the extension direction thereof, the electrode finger extension direction is parallel or substantially parallel to the direction in which the plurality of reflector electrode fingers of the reflector 9F extend. Thus, the resonance characteristic of the acoustic wave device can be more reliably made favorable.

The plurality of parallel regions may include, for example, a third parallel region, a fourth parallel region, and the like other than the first parallel region A1 and the second parallel region A2. Specifically, when n is defined as a natural number greater than or equal to two and k is defined as each natural number from one to n, the plurality of parallel regions may include k-th parallel regions. In the present example embodiment, n=2. Accordingly, k takes values of one and two. Thus, the plurality of parallel regions include the first parallel region A1 and the second parallel region A2. Meanwhile, for example, when n=3, k takes values of one, two, and three. Thus, the plurality of parallel regions include the first to third parallel regions. When n is a value greater than or equal to four, the plurality of parallel regions include the first to n-th parallel regions.

The smaller the value of k is, the larger the number of first electrode fingers and second electrode fingers included in the k-th region is. For example, the first parallel region includes all of the first electrode fingers and all of the second electrode fingers. Thus, among the k-th parallel regions, the number of electrode fingers included in the first parallel region is the largest. When k is other than one, the k-th parallel region includes a plurality of electrode fingers as a portion of all of the electrode fingers.

In the present example embodiment, in a portion where the second parallel region A2 is disposed, the first parallel region A1 and the second parallel region A2 are adjacent to each other. On the other hand, in a portion where the second parallel region A2 is not disposed, the first parallel regions A1 are adjacent to each other. In this manner, the parallel regions adjacent to each other differ depending on each portion in the intersection region. This also applies when n is a value greater than or equal to three. A specific arrangement of the plurality of parallel regions in a case in which n is three or more is described below.

For example, as shown in FIG. 15, two second parallel regions A2 are disposed such that one first parallel region A1 is interposed therebetween. Although not shown, when n=4, two third parallel regions are disposed such that one second parallel region is interposed therebetween. Two fourth parallel regions are disposed such that one third parallel region is interposed therebetween. When k is other than one, two k-th parallel regions are disposed such that one (k−1)-th parallel region is interposed therebetween.

As described above, the smaller the value of k is, the larger the number of electrode fingers included in the k-th region is. Thus, the number of electrode fingers included in the third parallel region is smaller than the number of electrode fingers included in the second parallel region, and the number of electrode fingers included in the fourth parallel region is smaller than the number of electrode fingers included in the third parallel region. Accordingly, in portions where the third parallel region and the fourth parallel region are not disposed, the second parallel region is adjacent to the first parallel region. Similarly, in portions where the fourth parallel region is not disposed, the third parallel region is adjacent to the second parallel region. In all portions where the fourth parallel region is disposed, the fourth parallel region is adjacent to the third parallel region.

As in these cases, the k-th parallel regions having consecutive values of k are adjacent to each other in at least a portion of the intersection region. The same applies to a case in which n is five or more. When n is three or more, the occupancy ratio of the parallel region in the intersection region can be further increased. Accordingly, the resonance characteristic of the acoustic wave device can be even more reliably made favorable.

It is preferable that n is a natural number less than or equal to, for example, about 90% of the number of pairs of electrode fingers in the IDT electrode. In this case, the acoustic wave device can be easily manufactured, and productivity can be improved.

FIG. 16 is a schematic plan view of an acoustic wave device according to a fourth example embodiment example embodiment.

The present example embodiment is different from the first example embodiment in that the first envelope E1 and the second envelope E2 extend in parallel or substantially in parallel with the direction in which the propagation axis of the piezoelectric layer 6 extends. The present example embodiment is different from the first example embodiment also in that a plurality of first offset electrodes 22 and a plurality of second offset electrodes 23 are bent. The shape of each reflector is made to correspond to the shape of an IDT electrode 28. Except for the above points, an acoustic wave device 21 of the present example embodiment has the same or substantially the same configuration as the acoustic wave device 1 of the first example embodiment.

Also in the present example embodiment, similarly to the first example embodiment, the parallel region A and the non-parallel region B are alternately disposed, and the plurality of electrode fingers each linearly extend in the plurality of parallel regions A and the non-parallel region B, and are each bent at the boundaries between the parallel region A and the non-parallel region B. Accordingly, out-of-band unwanted waves can be effectively reduced or prevented in the acoustic wave device 21.

As shown in FIG. 16, a plurality of first outer parallel regions C1 and a plurality of first outer non-parallel regions D1 are located between the intersection region J and the first busbar 14. In the present example embodiment, a portion of the first outer parallel regions C1 corresponds to a region obtained by extending the parallel region A toward the first busbar 14 side. In each first outer parallel region C1, the first electrode fingers 16 and the first offset electrodes 22 extend in parallel or substantially in parallel. On the other hand, a portion of the first outer non-parallel regions D1 corresponds to a region obtained by extending the non-parallel region B toward the first busbar 14 side. The first outer non-parallel region D1 is a region in which the directions in which the first electrode fingers 16 and the first offset electrodes 22 extend intersect each other.

Respective portions of the plurality of first offset electrodes 22 are included in the first outer parallel region C1 and the first outer non-parallel region D1. The first offset electrodes 22 linearly extend in the first outer parallel region C1 and the first outer non-parallel region D1, and are bent at the boundary between the first outer parallel region C1 and the first outer non-parallel region D1.

Similarly, a plurality of second outer parallel regions C2 and a plurality of second outer non-parallel regions D2 are located between the intersection region J and the second busbar 15. In each second outer parallel region C2, the second electrode fingers 17 and the second offset electrodes 23 extend in parallel or substantially in parallel. The second outer non-parallel region D2 is a region in which the directions in which the second electrode fingers 17 and the second offset electrodes 23 extend intersect each other. The second offset electrodes 23 linearly extend in the second outer parallel region C2 and the second outer non-parallel region D2, and are bent at the boundary between the second outer parallel region C2 and the second outer non-parallel region D2.

In a plurality of pairs of the first offset electrodes 22 and the second electrode fingers 17, linear portions including the tip portions of the first offset electrodes 22 and linear portions including the tip portions of the second electrode fingers 17 extend in parallel or substantially in parallel. Similarly, in a plurality of pairs of the second offset electrodes 23 and the first electrode fingers 16, linear portions including the tip portions of the second offset electrodes 23 and linear portions including the tip portions of the first electrode fingers 16 extend in parallel or substantially in parallel. This makes it possible to effectively reflect the main mode toward the intersection region J side. Accordingly, leakage of the main mode can be more reliably reduced or prevented.

The plurality of first offset electrodes may include the first offset electrode 22 that is bent and the first offset electrode that is not bent and has a linear shape. In this case, for example, it is sufficient that the first offset electrode that is not bent be located within one first outer parallel region C1. Meanwhile, it is sufficient that at least one first offset electrode 22 is bent. It is sufficient that the at least one first offset electrode 22 is included in at least one first outer parallel region C1 and the first outer non-parallel region D1 adjacent to this first outer parallel region C1. Similarly, the plurality of second offset electrodes may include the second offset electrode 23 that is bent and the second offset electrode that is not bent and has a linear shape. In this case, for example, it is sufficient that the second offset electrode that is not bent is located within one second outer parallel region C2. Meanwhile, it is sufficient that at least one second offset electrode 23 is bent. It is sufficient that the at least one second offset electrode 23 is included in at least one second outer parallel region C2 and the second outer non-parallel region D2 adjacent to this second outer parallel region C2.

Meanwhile, each electrode finger of the IDT electrode 28 is bent to be convex in the right direction in FIG. 16 as a whole. In the present specification, in the IDT electrode, the direction in which the electrode fingers are bent to be convex is defined as an outer direction, and the direction opposite to the outer direction is defined as an inner direction. That is, the right direction in FIG. 16 is the outer direction in the IDT electrode 28. The left direction in FIG. 16 is the inner direction in the IDT electrode 28.

Hereinafter, the number of sites included in different parallel regions A from each other in the electrode finger is referred to as the number of parallel region sites. In the electrode finger located innermost in the IDT electrode 28, the number of parallel region sites is seven, for example. On the other hand, in the electrode finger located outermost, the number of parallel region sites is three, for example. As described above, the plurality of electrode fingers include the electrode fingers having different numbers of parallel region sites from each other.

Specifically, the plurality of electrode fingers include a plurality of groups of the electrode fingers having different numbers of parallel region sites from each other. More specifically, in the acoustic wave device 21, the plurality of electrode fingers include a group of the electrode fingers located innermost in the IDT electrode 28, a group of the electrode fingers located near the center, and a group of the electrode fingers located outermost. In the group of the electrode fingers located innermost, the number of parallel region sites is seven, for example. In the group of the electrode fingers located near the center, the number of parallel region sites is five, for example. In the group of the electrode fingers located outermost, the number of parallel region sites is three, for example.

As described above, the plurality of electrode fingers in the acoustic wave device 21 include the plurality of groups of the electrode fingers having different numbers of parallel region sites from each other. Among these groups of the electrode fingers, the numbers of sites of portions among which the excitation angles θ_{C_prop} differ from each other in the electrode finger are different from each other. Accordingly, the range of variation in the frequency of unwanted waves excited differs for each portion where a respective one of the groups of the electrode fingers is located. Thus, the unwanted waves can be effectively dispersed. Specifically, out-of-band unwanted waves can be effectively dispersed. Accordingly, the out-of-band unwanted waves can be effectively reduced or prevented.

In the present example embodiment, any of the duty ratio, the electrode finger pitch, and the thickness of the electrode fingers varies in accordance with the excitation angle θ_{C_prop} such that the resonant frequencies or the anti-resonant frequencies substantially coincide with each other throughout the entire or substantially the entire intersection region J. Thus, similarly to the first example embodiment, the resonance characteristic can be more reliably made favorable.

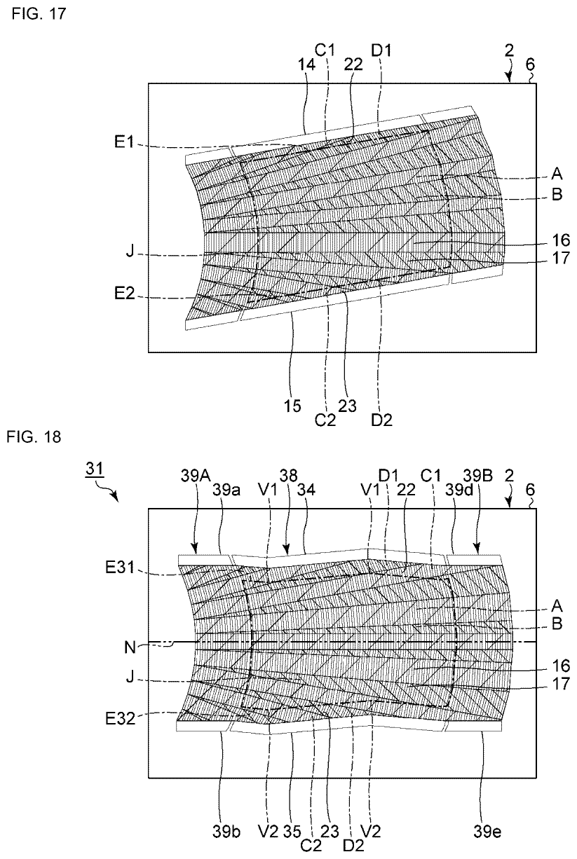

When the first envelope E1 and the second envelope E2 extend in parallel or substantially in parallel, the first envelope E1 and the second envelope E2 are not necessarily required to extend in parallel or substantially in parallel with the propagation axis of the piezoelectric layer 6. For example, in a modification of the fourth example embodiment shown in FIG. 17, the first envelope E1 and the second envelope E2 extend in parallel or substantially in parallel and extend obliquely with respect to the propagation axis. This can reduce or prevent the transverse mode.

Also in the present modification, similarly to the fourth example embodiment, the parallel region A and the non-parallel region B are alternately disposed, and the plurality of electrode fingers each linearly extend in the plurality of parallel regions A and the non-parallel region B, and are each bent at the boundaries between the parallel region A and the non-parallel region B. Accordingly, out-of-band unwanted waves can also be reduced or prevented in the acoustic wave device.

FIG. 18 is a schematic plan view of an acoustic wave device according to a fifth example embodiment of the present invention.

The present example embodiment is different from the fourth example embodiment in a configuration of an IDT electrode 38, a reflector 39A, and a reflector 39B. The shape of each reflector is made to correspond to the shape of the IDT electrode 38. Except for the above point, an acoustic wave device 31 of the present example embodiment has the same or substantially the same configuration as the acoustic wave device 21 of the fourth example embodiment.

A first envelope E31 in the acoustic wave device 31 includes a plurality of portions inclined with respect to the propagation axis. Further, the first envelope E31 includes a plurality of bending portions V1. Specifically, the bending portion is a portion at which the direction in which the envelope extends changes. In the present example embodiment, the shape of the first envelope E31 is a wave shape in which the adjacent bending portions V1 are connected to each other by a straight line. The shape of the first envelope E31 may be a wave shape in which the adjacent bending portions V1 are connected to each other by a curved line.

Similarly, a second envelope E32 also includes a plurality of portions inclined with respect to the propagation axis. The second envelope E32 includes a plurality of bending portions V2. The shape of the second envelope E32 is a wave shape in which the adjacent bending portions V2 are connected to each other by a straight line. The shape of the second envelope E32 may be a wave shape in which the adjacent bending portions V2 are connected to each other by a curved line.

As described above, in the present example embodiment, both of the first envelope E31 and the second envelope E32 include the plurality of bending portions. However, at least one of the first envelope E31 or the second envelope E32 may include at least one bending portion.

The IDT electrode 38 includes a plurality of segments with the electrode finger passing through the bending portion V1 of the first envelope E31 being a boundary. The plurality of segments are arranged in the direction in which the propagation axis extends. In FIG. 18, for example, three segments are schematically shown.

The excitation angle θ_{C_prop} at an end portion of the first envelope E31 or a portion located at the bending portion V1 is defined as a first on-envelope excitation angle θ_{C_AP1_m}. m is a natural number. The first on-envelope excitation angle θ_{C_AP1_m} can be defined for the end portion of the first envelope E31 or each bending portion V1. Specifically, sequentially from the above end portion and the bending portion V1 on the inner side of the IDT electrode 38, the m in the first on-envelope excitation angle θ_{C_AP1_m} is set to one, two, three, . . . . In this manner, the first on-envelope excitation angle θ_{C_AP1_m} at the portion located closer to the inner side is provided with a smaller value of m. For example, the excitation angle θ_{C_prop} at the portion located at the above end portion on the inner side is the first on-envelope excitation angle θ_{C_AP1_1}. The excitation angle θ_{C_prop} at the innermost bending portion V1 is the first on-envelope excitation angle θ_{C_AP1_2}.

Similarly, the excitation angle θ_{C_prop} at an end portion of the second envelope E32 or a portion located at the bending portion V2 is defined as a second on-envelope excitation angle θ_{C_AP2_m}. The second on-envelope excitation angle θ_{C_AP2_m} at the portion located closer to the inner side is provided with a smaller value of m.

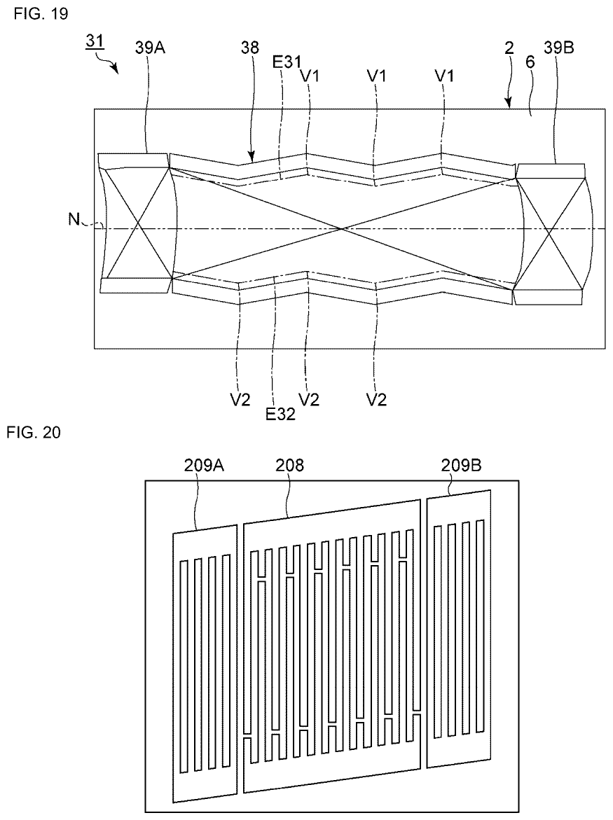

As described above, in FIG. 18, for example, three segments are schematically shown. However, the IDT electrode 38 includes, for example, five segments. Here, the five segments in the IDT electrode 38 are shown in FIG. 19 in a simplified manner. Each first on-envelope excitation angle θ_{C_AP1_m} and each second on-envelope excitation angle θ_{C_AP2_m} of the IDT electrode 38 are as follows:
First on-envelope excitation angle: θ_{C_AP1_1}=about 6.2°, θ_{C_AP1_2}=about 6.3°, θ_{C_AP1_3}=about 6.3°, θ_{C_AP1_4}=about 4.4°, θ_{C_AP1_5}=about 12°, θ_{C_AP1_6}=about 8.4°
Second on-envelope excitation angle: θ_{C_AP2_1}=about 14.3°, θ_{C_AP2_2}=about 8.8°, θ_{C_AP2_3}=about 12.5°, θ_{C_AP2_4}=about 6°, θ_{C_AP2_5}=about 4.2°, θ_{C_AP2_6}=about 12.3°

The shape of each electrode finger of the IDT electrode 38 in plan view is a shape bent at a plurality of nodes similarly to the fourth example embodiment. Specifically, in the intersection region J, the parallel region A and the non-parallel region B are alternately disposed, and the plurality of electrode fingers each linearly extend in the plurality of parallel regions A and the non-parallel region B, and are each bent at the boundaries between the parallel region A and the non-parallel region B. Accordingly, out-of-band unwanted waves can be effectively reduced or prevented in the acoustic wave device 31.

In the present example embodiment, the first envelope E31 and the second envelope E32 are inclined with respect to the propagation axis. This can reduce or prevent the transverse mode. Moreover, any of the duty ratio, the electrode finger pitch, and the thickness of the electrode fingers varies in accordance with the excitation angle θ_{C_prop} such that the resonant frequencies or the anti-resonant frequencies substantially coincide with each other throughout the entire intersection region J. Thus, similarly to the fourth example embodiment, the resonance characteristic can be more reliably made favorable. The above respective advantageous effects are specifically shown below by comparing the fifth example embodiment with a comparative example.

An acoustic wave device of a comparative example is a conventional inclined acoustic wave device as shown in FIG. 20. In the acoustic wave device of the comparative example, the shapes, in plan view, of each electrode finger and each reflector electrode finger in an IDT electrode 208, a reflector 209A, and a reflector 209B are linear shapes. A first busbar and a second busbar extend obliquely with respect to a normal direction to the electrode finger extension direction. The intersection region in the IDT electrode 208 has a parallelogram shape. An impedance frequency characteristic and a phase characteristic were compared between the fifth example embodiment and the comparative example. Results of the fourth example embodiment are also shown together. Further, return loss was compared between the fourth example embodiment and the fifth example embodiment.

In the acoustic wave device 31 of the fifth example embodiment relating to the comparison, the absolute value of the inclination angle of the first envelope E31 and the second envelope E32 with respect to the propagation axis was set to, for example, about 10°. The number of pairs of the electrode fingers between the bending portions V1 and the number of pairs of the electrode fingers between the bending portions V2 were set to, for example, 20 pairs. Meanwhile, in the acoustic wave device 21 of the fourth example embodiment relating to the comparison, the inclination angle of the first envelope E1 and the second envelope E2 with respect to the propagation axis is, for example, about 0°. The first envelope E1 and the second envelope E2 of the acoustic wave device 21 do not have the bending portion.

On the other hand, in the comparative example, a dimension of the intersection region along the electrode finger extension direction is defined as an intersecting width. The intersecting width in the IDT electrode 208 of the acoustic wave device of the comparative example is, for example, about 25λ. The number of pairs of the electrode fingers of the IDT electrode 208 is, for example, 100 pairs. In the IDT electrode 208, the duty ratio is, for example, 0.5. The angle at which each busbar is inclined with respect to a normal direction to the electrode finger extension direction is, for example, 7.5°.

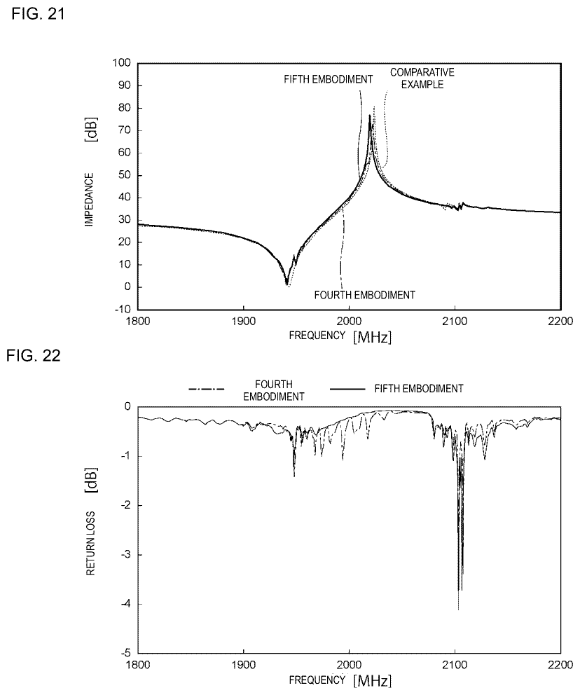

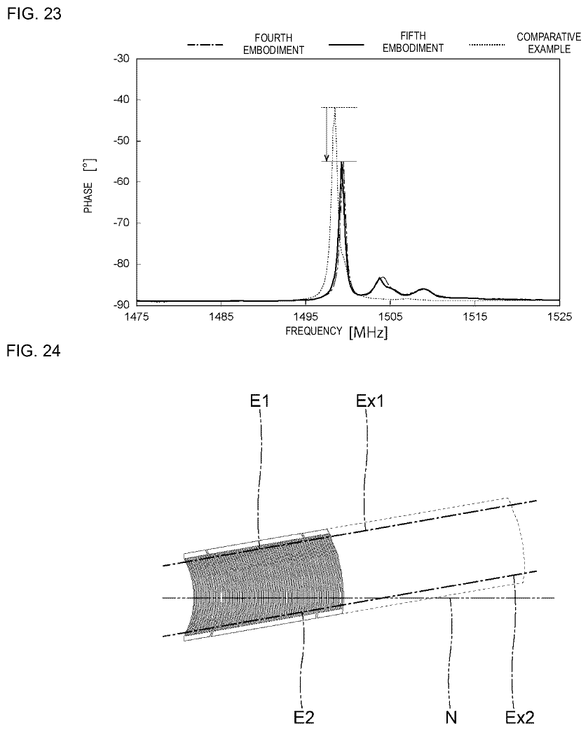

FIG. 21 is a diagram showing the impedance frequency characteristic in the fourth example embodiment, the fifth example embodiment, and the comparative example. FIG. 22 is a diagram showing the return loss in the fourth example embodiment and the fifth example embodiment. FIG. 23 is a diagram showing the phase characteristic on the lower frequency side relative to the resonant frequency in the fourth example embodiment, the fifth example embodiment, and the comparative example.

As shown in FIG. 21, there is no significant difference in the resonance characteristic among the fourth example embodiment, the fifth example embodiment, and the comparative example. That is, in the fourth example embodiment and the fifth example embodiment, deterioration of the resonance characteristic is reduced or prevented, and the resonance characteristic is favorable.

As shown in FIG. 22, in the fourth example embodiment, the transverse mode occurs around 2000 MHz, which is between the resonant frequency and the anti-resonant frequency. In contrast, it can be seen that the transverse mode is reduced or prevented in the fifth example embodiment.

As shown in FIG. 23, in the comparative example, a large unwanted wave occurs on the lower frequency side relative to the resonant frequency. The unwanted wave shown in FIG. 23 is a Rayleigh wave, for example. In contrast, it can be seen that, in the fourth example embodiment and the fifth example embodiment, the unwanted wave is reduced or prevented to a larger extent than in the comparative example. From the above, in the fourth example embodiment, the Rayleigh wave as the unwanted wave can be reduced or prevented. In the fifth example embodiment, both of the transverse mode and the Rayleigh wave as unwanted waves can be reduced or prevented.

In the fifth example embodiment shown in FIG. 18, similarly to the fourth example embodiment, out-of-band unwanted waves can be reduced or prevented due to the alternate disposition of the parallel region A and non-parallel region B. In addition, in the fifth example embodiment, similarly to the fourth example embodiment, the numbers of sites of portions among which the excitation angles θ_{C_prop} differ from each other are different from each other among the plurality of groups of the electrode fingers. Accordingly, out-of-band unwanted waves can be effectively reduced or prevented.

Moreover, in the fifth example embodiment, both reduction or prevention of unwanted waves and an increase in the quality factor can be achieved. This is because the first envelope E31 and the second envelope E32 in the fifth example embodiment include the bending portions. Details of this are described below with reference to a modification of the fourth example embodiment.

In the acoustic wave device of the modification of the fourth example embodiment schematically shown in FIG. 24, the first envelope E1 and the second envelope E2 do not include the bending portion. A dash-dot line Ex1 in FIG. 24 is an extension line of the first envelope E1. A dash-dot line Ex2 is an extension line of the second envelope E2. As described above, in the present modification, the first envelope E1 and the second envelope E2 are inclined with respect to the propagation axis.

In general, in order to make the resonance characteristic of an acoustic wave device favorable, the number of pairs of electrode fingers of an IDT electrode is increased. Further, in the acoustic wave device, in general, characteristics of a component propagating in the direction in which the propagation axis extends are the most favorable among characteristics of respective components in the main mode. The dash-dot-dot line N shown in FIG. 24 indicates a portion where the main mode propagates in the direction in which the propagation axis extends. Specifically, the dash-dot-dot line N is a virtual line indicating a portion where a normal direction to the electrode finger extension direction in the parallel region is parallel or substantially parallel to the direction in which the propagation axis extends.

For example, it is conceivable that the number of pairs of the electrode fingers is increased up to a portion indicated by a dashed line in FIG. 24 in order to further increase the quality factor and make the resonance characteristic more favorable in the present modification. However, in this case, the IDT electrode includes many electrode fingers that are not located on the dash-dot-dot line N. That is, the proportion of the portion through which the main mode does not propagate in the direction in which the propagation axis extends in the IDT electrode increases. In this case, it becomes difficult to further increase the quality factor.

On the other hand, in the fifth example embodiment, the portion on the dash-dot-dot line N in FIG. 18 is the portion through which the main mode propagates in the direction in which the propagation axis extends. In the acoustic wave device 31, the first envelope E31 and the second envelope E32 include the bending portions. Thus, the proportion of the portion through which the main mode propagates in the direction in which the propagation axis extends can be increased. Accordingly, the quality factor can be further increased.

It is preferable that, for example, about 50% or more of all of the electrode fingers include a portion where a normal direction to the direction in which the electrode finger extends is the same or substantially the same as the direction in which the propagation axis extends. It is more preferable that, for example, about 80% or more of all of the electrode fingers include the portion where a normal direction to the direction in which the electrode finger extends is the same or substantially the same as the direction in which the propagation axis extends. With this configuration, the quality factor can be more reliably increased. In the fifth example embodiment, all of the electrode fingers include the portion where a normal direction to the direction in which the electrode finger extends is the same or substantially the same as the direction in which the propagation axis extends. Thus, the quality factor can be further increased even more reliably.

It is preferable that the first envelope E31 includes a plurality of bending portions V1 as in the fifth example embodiment. This makes it possible to provide a configuration in which an even larger number of electrode fingers include the portion where a normal direction to the electrode finger extension direction is the same or substantially the same as the direction in which the propagation axis extends. Accordingly, the quality factor can be more reliably increased.

As shown in FIG. 18, in the fifth example embodiment, the shape, in plan view, of the portion of a first busbar 34 on the first envelope E31 side is a wave shape. A distance between the first busbar 34 and the first envelope E31 in a direction orthogonal or substantially orthogonal to the propagation axis is constant. Further, the gap length of the gap between the tip portion of the second electrode finger 17 and the tip portion of the first offset electrode 22 is also constant. As described above, in accordance with the shape of the first envelope E31, the above gap length can be maintained constant without increasing the length of the first offset electrode 22. Thus, leakage of the main mode can be more reliably reduced or prevented without increasing the electrical resistance of the IDT electrode 38.

Similarly, a distance between a second busbar 35 and the second envelope E32 in a direction orthogonal or substantially orthogonal to the propagation axis is constant. The gap length of the gap between the tip portion of the first electrode finger 16 and the tip portion of the second offset electrode 23 is also constant. Thus, leakage of the main mode can be more reliably reduced or prevented without increasing the electrical resistance of the IDT electrode 38.

In the fifth example embodiment, a dimension corresponding to the period and a dimension corresponding to the amplitude in the wave shape in the first envelope E31 are constant. Specifically, the dimension corresponding to the above period is a component, in the direction in which the propagation axis extends, of the distance between the bending portions V1 at both end portions among three consecutive bending portions V1. The dimension corresponding to the above amplitude is a component, in a direction orthogonal or substantially orthogonal to the propagation axis, of the distance between adjacent bending portions V1. In the first envelope E31, at least one of the dimension corresponding to the period or the dimension corresponding to the amplitude in the wave shape is not required to be constant. For example, in the first envelope E31, the dimension corresponding to the period and the dimension corresponding to the amplitude in the wave shape may be made random. In this case, the transverse mode can be effectively reduced or prevented.

A dimension corresponding to the period and a dimension corresponding to the amplitude in the wave shape of the second envelope E32 can also be defined similarly to the first envelope E31. Also in the second envelope E32, at least one of the dimension corresponding to the period or the dimension corresponding to the amplitude in the wave shape is not required to be constant. For example, in the second envelope E32, the dimension corresponding to the period and the dimension corresponding to the amplitude in the wave shape may be made random.

In the fifth example embodiment, in each of the first envelope E31 and the second envelope E32, the absolute value of the inclination angle with respect to the propagation axis is constant. In example embodiments of the present invention, the absolute value of the inclination angle with respect to the propagation axis is not required to be constant in each of the first envelope E31 and the second envelope E32. For example, the above inclination angle may be made random.

A reflector busbar 39a and a reflector busbar 39b of the reflector 39A in the acoustic wave device 31 extend in parallel or substantially in parallel with the direction in which the propagation axis extends. Similarly, a reflector busbar 39d and a reflector busbar 39e of the reflector 39B extend in parallel or substantially in parallel with the direction in which the propagation axis extends. However, similarly to the first example embodiment, each reflector busbar of each reflector may extend obliquely with respect to the propagation axis. Alternatively, a shape at a portion of each reflector busbar on the reflector electrode finger side in plan view may be a wave shape similarly to each busbar of the IDT electrode 38.

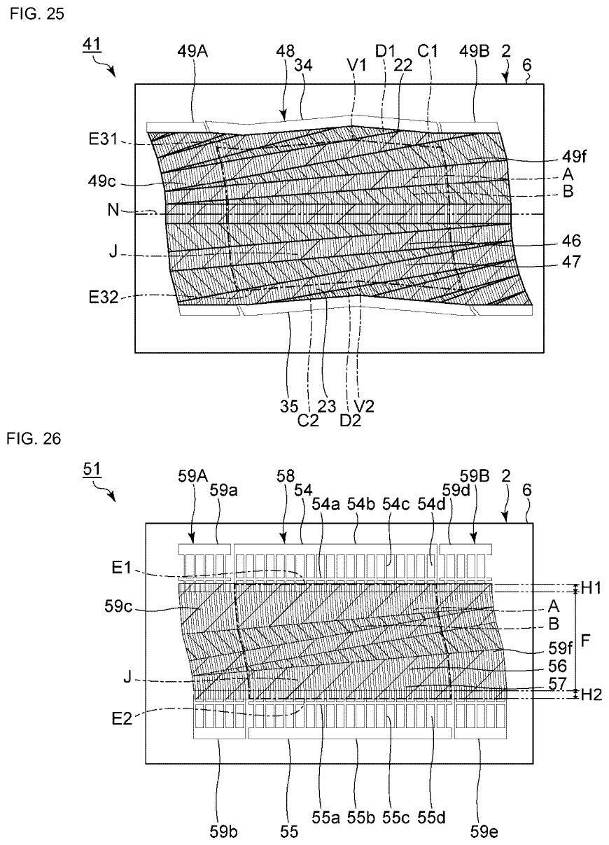

FIG. 25 is a schematic plan view of an acoustic wave device according to a sixth example embodiment of the present invention.

The present example embodiment is different from the fifth example embodiment in a configuration of an IDT electrode 48, a reflector 49A, and a reflector 49B. The shape of each reflector is made to correspond to the shape of the IDT electrode 48. Except for the above point, an acoustic wave device 41 of the present example embodiment has the same or substantially the same configuration as the acoustic wave device 31 of the fifth example embodiment.

In the acoustic wave device 41, a plurality of first electrode fingers 46 and a plurality of second electrode fingers 47 each include two portions between which directions in which the electrode finger is bent differ from each other. Specifically, each electrode finger includes a portion bent to be convex in the right direction in FIG. 25 and a portion bent to be convex in the left direction. In the present example embodiment, with the dash-dot-dot line N in FIG. 25 being a boundary, the shapes of the two portions of each electrode finger are inverted with respect to each other. The shape of each electrode finger in plan view can be approximated by a shape obtained by connecting circular arcs, elliptical arcs, or parabolas to each other.

In the present example embodiment, the boundary between the two portions in each electrode finger, between which the directions in which the electrode finger is bent differ from each other, extends in parallel or substantially in parallel with the direction in which the propagation axis extends. However, this boundary may extend obliquely with respect to the propagation axis.

The shape of each electrode finger in the intersection region in plan view may include, for example, three or more portions among which the directions in which the electrode finger is bent differ from each other. In this case, it is only required that the directions in which the electrode finger is bent differ from each other between adjacent portions.

Also in the present example embodiment, similarly to the fifth example embodiment, the parallel region A and the non-parallel region B are alternately disposed, and the plurality of electrode fingers each linearly extend in the plurality of parallel regions A and the non-parallel region B, and are each bent at the boundaries between the parallel region A and the non-parallel region B. Accordingly, out-of-band unwanted waves can be effectively reduced or prevented in the acoustic wave device 41. In addition, the first envelope E31 and the second envelope E32 are inclined with respect to the propagation axis of the piezoelectric layer 6. This can reduce or prevent the transverse mode. Moreover, the first envelope E31 and the second envelope E32 each have the plurality of bending portions. This can increase the quality factor.

In the present example embodiment, the shapes of the plurality of electrode fingers in plan view are made point-symmetric or substantially point-symmetric. In this case, each electrode finger includes a portion curved to be convex toward the reflector 49A side and a portion curved to be convex toward the reflector 49B side. Further, when the piezoelectric layer 6 is a single-crystal film having material anisotropy, the signs of the phase sometimes become opposite to each other between an unwanted wave propagating toward the reflector 49A side and an unwanted wave propagating toward the reflector 49B side. In this case, the unwanted wave can be effectively reduced or prevented. When the piezoelectric layer 6 is a single-crystal film using, for example, lithium niobate or lithium tantalate, the piezoelectric layer 6 is a single-crystal film having material anisotropy.

As shown in FIG. 25, similarly to the shape of each electrode finger of the IDT electrode 48 in plan view, the shape of each reflector electrode finger 49c of the reflector 49A and each reflector electrode finger 49f of the reflector 49B in plan view includes two portions between which directions in which the reflector electrode finger is bent differ from each other.

FIG. 26 is a schematic plan view of an acoustic wave device according to a seventh example embodiment of the present invention.

The present example embodiment is different from the first example embodiment in a configuration of an IDT electrode 58, a reflector 59A, and a reflector 59B. The shape of each reflector is made to correspond to the shape of the IDT electrode 58. Except for the above point, an acoustic wave device 51 of the present example embodiment has the same or substantially the same configuration as the acoustic wave device 1 of the first example embodiment.

Similarly to the sixth example embodiment, a plurality of first electrode fingers 56 and a plurality of second electrode fingers 57 each include two portions between which directions in which the electrode finger is bent differ from each other. However, the first envelope E1 and the second envelope E2 extend in parallel or substantially in parallel with the direction in which the propagation axis extends.

A plurality of openings 54d are provided in a first busbar 54. Specifically, the first busbar 54 includes a first inner busbar portion 54a, a first outer busbar portion 54b, and a plurality of first connection portions 54c. The first inner busbar portion 54a and the first outer busbar portion 54b are opposite to each other. Of the first inner busbar portion 54a and the first outer busbar portion 54b, the first inner busbar portion 54a is located on the intersection region J side. The plurality of first connection portions 54c connect the first inner busbar portion 54a and the first outer busbar portion 54b. The plurality of openings 54d are each an opening surrounded by the first inner busbar portion 54a, the first outer busbar portion 54b, and the plurality of first connection portions 54c.

Similarly, a second busbar 55 also includes a second inner busbar portion 55a, a second outer busbar portion 55b, and a plurality of second connection portions 55c. A plurality of openings 55d are provided in the second busbar 55.

The first inner busbar portion 54a extends in parallel or substantially in parallel with the first envelope E1. The first inner busbar portion 54a is opposite to the plurality of second electrode fingers 57 with a gap therebetween. The second inner busbar portion 55a extends in parallel or substantially in parallel with the second envelope E2. The second inner busbar portion 55a is opposite to the plurality of first electrode fingers 56 with a gap therebetween.

The intersection region J of the IDT electrode 58 includes a central region F and a pair of edge regions. Specifically, the pair of edge regions include a first edge region H1 and a second edge region H2. The first edge region H1 includes the first envelope E1 as an edge portion. The second edge region H2 includes the second envelope E2 as an edge portion. The first edge region H1 and the second edge region H2 are opposite to each other with the central region F interposed therebetween. The respective intersection regions of the other example embodiments also include the first edge region, the second edge region, and the central region.

In the present example embodiment, the plurality of first connection portions 54c of the first busbar 54 each extend on an extension line of the first electrode finger 56. The plurality of first connection portions 54c are not disposed on extension lines of the second electrode fingers 57. Meanwhile, in the intersection region J, the first electrode fingers 56 and the second electrode fingers 57 are alternately arranged. Accordingly, the acoustic velocity in a region in which the plurality of openings 54d are provided in the first busbar 54 is higher than the acoustic velocity in the intersection region J. Thus, a high acoustic velocity region is provided in the region in which the openings 54d are provided in the first busbar 54. The high acoustic velocity region is a region in which the acoustic velocity is higher than that in the central region F. Similarly, a high acoustic velocity region is also provided in a region in which the openings 55d are provided in the second busbar 55.

Leakage of energy of the acoustic wave sometimes occurs in association with mode conversion of the main mode. For example, when an SH wave is used as the main mode of the acoustic wave, energy of the acoustic wave leaks due to conversion from the SH wave to a Rayleigh wave or from the SH wave to a bulk wave. Such leakage occurs from the intersection region side toward the busbar side.

In the present example embodiment, the first inner busbar portion 54a is opposite to the plurality of second electrode fingers 57 with a gap therebetween. This can reduce or prevent leakage of energy of the acoustic wave associated with the mode conversion. Further, the second inner busbar portion 55a is opposite to the plurality of first electrode fingers 56 with a gap therebetween. This can reduce or prevent leakage of energy of the acoustic wave associated with the mode conversion.

It is preferable that the distance between the first inner busbar portion 54a and the second electrode finger 57 is, for example, about 0.5 λ or less. Similarly, it is preferable that the distance between the second inner busbar portion 55a and the first electrode finger 56 is, for example, about 0.5 λ or less. This can effectively reduce or prevent leakage of energy of the acoustic wave associated with the mode conversion.

In addition, the high acoustic velocity region is provided between the first inner busbar portion 54a and the first outer busbar portion 54b. This allows energy of the acoustic wave to be effectively confined to the intersection region J side. Similarly, the high acoustic velocity region is provided between the second inner busbar portion 55a and the second outer busbar portion 55b. This allows energy of the acoustic wave to be effectively confined to the intersection region J side.

Also in the present example embodiment, similarly to the first example embodiment, the parallel region A and the non-parallel region B are alternately disposed, and the plurality of electrode fingers each linearly extend in the plurality of parallel regions A and the non-parallel region B, and are each bent at the boundaries between the parallel region A and the non-parallel region B. Accordingly, out-of-band unwanted waves can be effectively reduced or prevented in the acoustic wave device 51.

As shown in FIG. 26, similarly to the shape of each electrode finger of the IDT electrode 58 in plan view, the shape of each reflector electrode finger 59c of the reflector 59A and each reflector electrode finger 59f of the reflector 59B in plan view includes two portions between which directions in which the reflector electrode finger is bent differ from each other. A plurality of openings are provided in each of a reflector busbar 59a of the reflector 59A and a reflector busbar 59d of the reflector 59B, similarly to the first busbar 54. A plurality of openings are provided in each of a reflector busbar 59b of the reflector 59A and a reflector busbar 59e of the reflector 59B, similarly to the second busbar 55. However, the openings are not necessarily required to be provided in each reflector busbar of each reflector.

In the seventh example embodiment, the first envelope E1 and the second envelope E2 extend in parallel or substantially in parallel with the direction in which the propagation axis extends. However, even when the first envelope E31 includes the plurality of bending portions V1 as in the sixth example embodiment shown in FIG. 25, the first busbar may include a first inner busbar portion, a first outer busbar portion, and a plurality of first connection portions. The same applies to the second busbar.

Meanwhile, the configuration of acoustic wave devices according to example embodiments of the present invention may be a configuration that enables use of a piston mode. An example of the configuration that enables use of a piston mode is shown in an eighth example embodiment of the present invention.

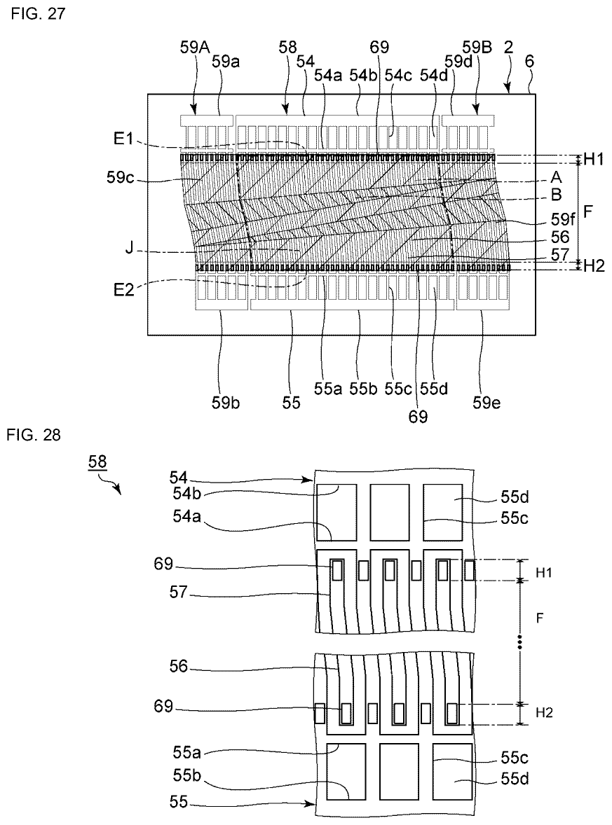

FIG. 27 is a schematic plan view of an acoustic wave device according to the eighth example embodiment. FIG. 28 is a schematic enlarged plan view showing vicinities of the first edge region and the second edge region in the eighth example embodiment.

As shown in FIG. 27, the present example embodiment is different from the seventh example embodiment in that a mass addition film 69 is disposed on each electrode finger and on each reflector electrode finger. Except for the above point, the acoustic wave device of the present example embodiment has the same or substantially the same configuration as the acoustic wave device 51 of the seventh example embodiment.

As shown in FIG. 28, a plurality of mass addition films 69 are disposed in the first edge region H1. Specifically, in the first edge region H1, the mass addition film 69 is disposed on each first electrode finger 56 and on each second electrode finger 57. Thus, a low acoustic velocity region is provided in the first edge region H1. The low acoustic velocity region is a region in which the acoustic velocity is lower than that in the central region F.

Referring back to FIG. 27, a plurality of mass addition films 69 are also disposed in the second edge region H2 similarly to the first edge region H1. Thus, a low acoustic velocity region is also provided in the second edge region H2. In the present example embodiment, the mass addition films 69 are each disposed only on one electrode finger. In this case, an appropriate metal or dielectric can be used as a material of the mass addition film 69.

In respective regions obtained by extending each edge region in a direction in which the first busbar 54 extends, the mass addition film 69 is also disposed on each reflector electrode finger 59c of the reflector 59A. Similarly, the mass addition film 69 is also disposed on each reflector electrode finger 59f of the reflector 59B. However, the mass addition film 69 is not required to be disposed on each reflector electrode finger.

In the present example embodiment, from the inner side toward the outer side in a direction in which the first busbar 54 and the second busbar 55 are opposite to each other, the central region F and the pair of low acoustic velocity regions are disposed in that order. Thus, the piston mode is generated. Accordingly, energy of the main mode can be effectively confined to the central side of the intersection region J, and characteristics of the main mode can be made favorable. Further, the transverse mode can be reduced or prevented.

In addition, the IDT electrode 58 in the present example embodiment is provided similarly to the seventh example embodiment. Thus, leakage of energy of the acoustic wave associated with mode conversion can be reduced or prevented. Further, out-of-band unwanted waves can be effectively reduced or prevented.

It is sufficient that the low acoustic velocity region is provided in at least one of the first edge region H1 or the second edge region H2. However, it is preferable that the low acoustic velocity regions is provided in both the first edge region H1 and the second edge region H2. With this configuration, the piston mode can be more reliably generated.

The mass addition film 69 is only required to be laminated with at least one of the plurality of electrode fingers in at least one of the first edge region H1 or the second edge region H2. Specifically, the mass addition film 69 is only required to be disposed so as to overlap, in plan view, at least one of the plurality of first electrode fingers 56 and the plurality of second electrode fingers 57 in at least one of the first edge region H1 or the second edge region H2. In this case, the low acoustic velocity region is provided in at least a portion of at least one of the first edge region H1 or the second edge region H2.

It is preferable that a plurality of electrode fingers are laminated with the mass addition films 69 in at least one of the first edge region H1 or the second edge region H2, and it is more preferable that all of the electrode fingers are laminated with the mass addition films 69 therein. Alternatively, it is more preferable that a plurality of electrode fingers are laminated with the mass addition films 69 in both of the first edge region H1 and the second edge region H2. With this configuration, the piston mode can be more reliably generated. It is still more preferable that all of the electrode fingers are laminated with the mass addition films 69 in both edge regions. In this case, the low acoustic velocity regions are provided over the entire or substantially the entire regions of both edge regions. Thus, the piston mode can be even more reliably generated.

In the present example embodiment, in a portion where the electrode finger and the mass addition film 69 are laminated, the layers are laminated in order of the piezoelectric substrate 2, the electrode finger, and the mass addition film 69. However, in the portion where the electrode finger and the mass addition film 69 are laminated, the layers may be laminated in order of the piezoelectric substrate 2, the mass addition film 69, and the electrode finger. That is, the mass addition film 69 may be disposed between the piezoelectric substrate 2 and the electrode finger.

In the present example embodiment, the first envelope E1 and the second envelope E2 extend in parallel or substantially in parallel with the direction in which the propagation axis extends. However, even when the first envelope E31 includes the plurality of bending portions V1 as in the sixth example embodiment shown in FIG. 25, a plurality of mass addition films 69 may be disposed in the first edge region. This may define a low acoustic velocity region in the first edge region.

Similarly, even when the second envelope E32 includes the plurality of bending portions V2, a plurality of mass addition films 69 may be disposed in the second edge region. This may define a low acoustic velocity region in the second edge region.

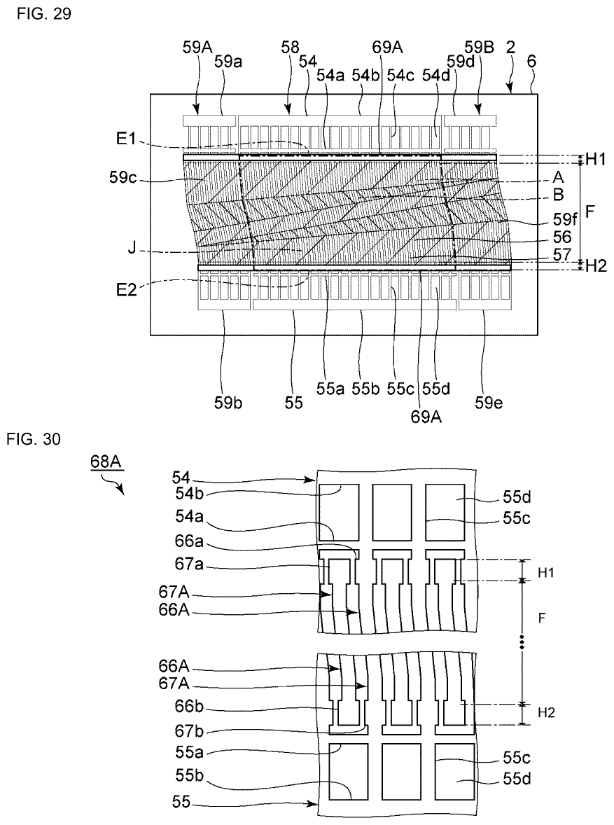

One mass addition film 69 may be disposed to extend over a plurality of electrode fingers. For example, in a first modification of the eighth example embodiment shown in FIG. 29, one mass addition film 69A is disposed in each of the first edge region H1 and the second edge region H2. Thus, a low acoustic velocity region is provided in each of the first edge region H1 and the second edge region H2.

Specifically, each mass addition film 69A has a strip shape. Of the pair of mass addition films 69A, one mass addition film 69A is disposed to extend over a plurality of electrode fingers in the first edge region H1. Similarly, the other mass addition film 69A is disposed to extend over a plurality of electrode fingers in the second edge region H2. Each mass addition film 69A is also disposed on portions between the electrode fingers on the piezoelectric layer 6. An appropriate dielectric can be used as a material of the mass addition film 69A.

The mass addition film 69A is only required to be laminated with at least one of the plurality of electrode fingers in at least one of the first edge region H1 or the second edge region H2. In this case, the mass addition film 69A may be disposed to extend over the electrode fingers and portions between the electrode fingers. However, it is preferable that a plurality of electrode fingers are laminated with the mass addition film 69A in at least one of the first edge region H1 or the second edge region H2, and it is more preferable that all of the electrode fingers are laminated with the mass addition film 69A therein. It is more preferable that a plurality of electrode fingers are laminated with the mass addition film 69A in both of the first edge region H1 and the second edge region H2, and it is still more preferable that all of the electrode fingers are laminated with the mass addition film 69A therein. With this configuration, the piston mode can be more reliably generated.

In the present modification, the IDT electrode 58 is provided similarly to the seventh and eighth example embodiments. Thus, leakage of energy of the acoustic wave associated with mode conversion can be reduced or prevented, and out-of-band unwanted waves can be effectively reduced or prevented.

On the other hand, in a second modification of the eighth example embodiment shown in FIG. 30, each electrode finger of an IDT electrode 68A includes a wide portion in the first edge region H1 and the second edge region H2. The width of the electrode finger in the wide portion is greater than that of this electrode finger in the central region F. In the present modification, the mass addition film is not provided.

Specifically, first electrode fingers 66A include wide portions 66a in the first edge region H1. Second electrode fingers 67A also include wide portions 67a in the first edge region H1. Meanwhile, the first electrode fingers 66A include wide portions 66b in the second edge region H2. The second electrode fingers 67A also include wide portions 67b in the second edge region H2. Thus, the acoustic velocity in the first edge region H1 and the second edge region H2 is lower than that in the central region F. Accordingly, low acoustic velocity regions are provided in the first edge region H1 and the second edge region H2.

It is sufficient that at least one electrode finger includes the wide portion in at least one of the first edge region H1 or the second edge region H2. However, it is preferable that a plurality of electrode fingers include the wide portions in at least one of the first edge region H1 or the second edge region H2, and it is more preferable that all of the electrode fingers include the wide portions therein. Further, it is more preferable that a plurality of electrode fingers include the wide portions in both of the first edge region H1 and the second edge region H2, and it is still more preferable that all of the electrode fingers include the wide portions therein. With this configuration, the piston mode can be more reliably generated.

In the present modification, the width of each electrode finger is increased throughout the entire or substantially the entire edge regions. A shape of each wide portion in plan view is quadrangular or substantially quadrangular. However, each electrode finger may have an increased width in at least a portion of each edge region. The shape of each wide portion in plan view is not limited to the quadrangular or substantially quadrangular shape. Each reflector electrode finger of each reflector may also include a wide portion.

In the central region F, the IDT electrode 68A of the present modification is provided similarly to the seventh and eighth example embodiments. Thus, out-of-band unwanted waves can be effectively reduced or prevented. In addition, the first inner busbar portion 54a is opposite to the plurality of second electrode fingers 67A with a gap therebetween. The second inner busbar portion 55a is opposite to the plurality of first electrode fingers 66A with a gap therebetween. This can reduce or prevent leakage of energy of the acoustic wave associated with mode conversion.

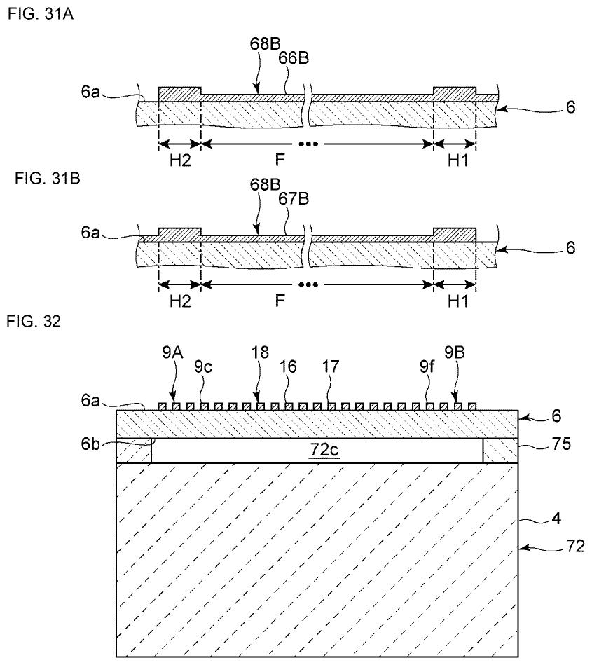

Referring back to FIG. 27, the same metal as that used for each electrode finger may be used as the material of the mass addition film 69. This configuration corresponds to a configuration of a third modification of the eighth example embodiment shown in FIGS. 31A and 31B. That is, as shown in FIG. 31A, the thickness of a first electrode finger 66B in the first edge region H1 and the second edge region H2 is greater than that of the first electrode finger 66B in the central region F. As shown in FIG. 31B, the thickness of a second electrode finger 67B in the first edge region H1 and the second edge region H2 is greater than that of the second electrode finger 67B in the central region F. Thus, a low acoustic velocity region is provided in each of the first edge region H1 and the second edge region H2.

In FIG. 31A, sections along the electrode finger extension direction at respective portions of the first electrode finger 66B are connected to each other and schematically shown. In FIG. 31B, sections along the electrode finger extension direction at respective portions of the second electrode finger 67B are connected to each other and schematically shown.

It is sufficient that the thickness of at least one electrode finger in at least one of the first edge region H1 or the second edge region H2 is greater than that of the electrode finger in the central region F. However, it is preferable that the thicknesses of a plurality of electrode fingers in at least one of the first edge region H1 or the second edge region H2 are each greater than that of these electrode fingers in the central region F. It is more preferable that the thicknesses of all of the electrode fingers in at least one of the first edge region H1 or the second edge region H2 are each greater than that of these electrode fingers in the central region F.

Further, it is more preferable that the thicknesses of a plurality of electrode fingers in both of the first edge region H1 and the second edge region H2 are each greater than that of these electrode fingers in the central region F. It is still more preferable that the thicknesses of all of the electrode fingers in both of the first edge region H1 and the second edge region H2 are each greater than that of these electrode fingers in the central region F. With this configuration, the piston mode can be more reliably generated.

In the present modification, the thickness of each electrode finger is increased throughout the entire or substantially the entire edge regions. However, each electrode finger may have an increased thickness in at least a portion of each edge region. Each reflector electrode finger of each reflector may also have an increased thickness in respective regions obtained by extending the edge region in the direction in which the first busbar 54 extends.

A configuration of an IDT electrode 68B in the present modification corresponds to a configuration in which the material of the mass addition film 69 disposed on each electrode finger of the IDT electrode 58 in the eighth example embodiment is the same as the material of each electrode finger. Thus, leakage of energy of the acoustic wave associated with mode conversion can be reduced or prevented, and out-of-band unwanted waves can be effectively reduced or prevented.

In example embodiments of the present invention, the piston mode may be generated by at least one of the configuration in which the thickness of the electrode finger is increased, the configuration in which the electrode finger has the wide portion, or the configuration in which the mass addition film is disposed. When both of the configuration in which the thickness of the electrode finger is increased and the configuration in which the mass addition film is disposed are provided, it is only required that a material used for the mass addition film is made different from a material used for the electrode finger.

Meanwhile, in acoustic wave devices according to example embodiments of the present invention, the multilayer configuration of the piezoelectric substrate is not limited to the configuration shown in FIG. 2. An example in which an acoustic wave device includes a piezoelectric substrate different from that in the first example embodiment is shown in a ninth example embodiment of the present invention.

FIG. 32 is a schematic elevational cross-sectional view of an acoustic wave device according to the ninth example embodiment.

The present example embodiment is different from the first example embodiment in a multilayer configuration of a piezoelectric substrate 72. Except for the above point, the acoustic wave device of the present example embodiment has the same or substantially the same configuration as the acoustic wave device 1 of the first example embodiment.

The piezoelectric substrate 72 includes the support substrate 4, an intermediate layer 75, and the piezoelectric layer 6. The intermediate layer 75 is disposed on the support substrate 4. The piezoelectric layer 6 is disposed on the intermediate layer 75. In the present example embodiment, the intermediate layer 75 has a frame shape. That is, the intermediate layer 75 includes a through-hole. The support substrate 4 closes one side of the through-hole of the intermediate layer 75. The piezoelectric layer 6 closes the other side of the through-hole of the intermediate layer 75. Thus, a hollow portion 72c is provided in the piezoelectric substrate 72. A portion of the piezoelectric layer 6 and a portion of the support substrate 4 are opposite to each other with the hollow portion 72c interposed therebetween.

In the present example embodiment, the main mode can be reflected toward the piezoelectric layer 6 side. Thus, energy of the acoustic wave can be effectively confined to the piezoelectric layer 6 side. In addition, similarly to the first example embodiment, unwanted waves can be effectively reduced or prevented.

First and second modifications of the ninth example embodiment, which are different from the ninth example embodiment only in a multilayer configuration of a piezoelectric substrate, are shown below. Also in the first and second modifications, unwanted waves can be effectively reduced or prevented similarly to the ninth example embodiment. Further, energy of the acoustic wave can be effectively confined to the piezoelectric layer 6 side.

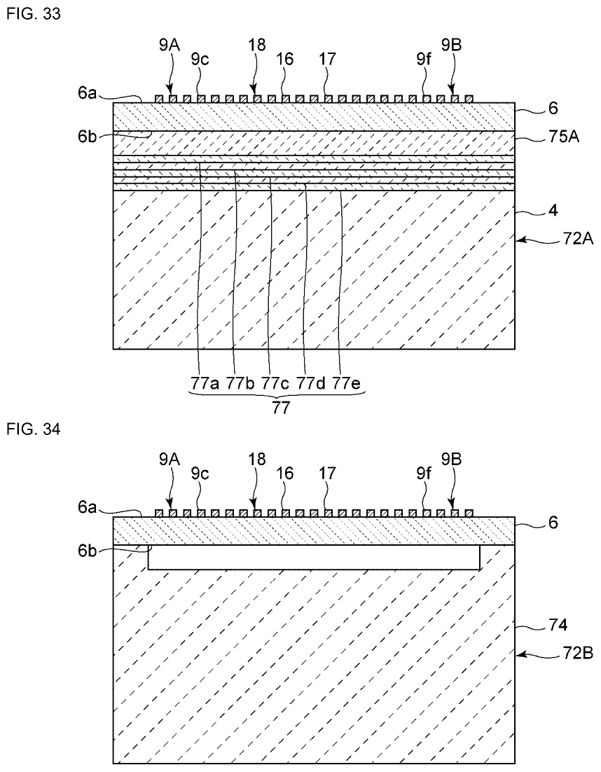

In the first modification shown in FIG. 33, a piezoelectric substrate 72A includes the support substrate 4, an acoustic reflection film 77, an intermediate layer 75A, and the piezoelectric layer 6. The acoustic reflection film 77 is disposed on the support substrate 4. The intermediate layer 75A is disposed on the acoustic reflection film 77. The piezoelectric layer 6 is disposed on the intermediate layer 75A. The intermediate layer 75A is a low acoustic velocity film.

The acoustic reflection film 77 is a multilayer body including a plurality of acoustic impedance layers. Specifically, the acoustic reflection film 77 includes a plurality of low acoustic impedance layers and a plurality of high acoustic impedance layers. The high acoustic impedance layer is a layer having a relatively high acoustic impedance. More specifically, the plurality of high acoustic impedance layers of the acoustic reflection film 77 are high acoustic impedance layers 77a, 77c, and 77e. Meanwhile, the low acoustic impedance layer is a layer having a relatively low acoustic impedance. More specifically, the plurality of low acoustic impedance layers of the acoustic reflection film 77 are low acoustic impedance layers 77b and 77d. The low acoustic impedance layers and the high acoustic impedance layers are alternately laminated. The high acoustic impedance layer 77a is a layer located closest to the piezoelectric layer 6 in the acoustic reflection film 77.

The acoustic reflection film 77 includes, for example, two low acoustic impedance layers and three high acoustic impedance layers. However, the acoustic reflection film 77 is only required to include at least one low acoustic impedance layer and at least one high acoustic impedance layer.

As a material of the low acoustic impedance layer, for example, silicon oxide, aluminum, or the like can be used. As a material of the high acoustic impedance layer, for example, a metal such as platinum or tungsten or a dielectric such as aluminum nitride or silicon nitride can be used. A material of the intermediate layer 75A may be the same as that of the low acoustic impedance layer.

In the second modification shown in FIG. 34, a piezoelectric substrate 72B includes a support substrate 74 and the piezoelectric layer 6. The piezoelectric layer 6 is directly disposed on the support substrate 74. Specifically, the support substrate 74 includes a recess. The piezoelectric layer 6 is disposed on the support substrate 74 so as to close the recess. Thus, a hollow portion is provided in the piezoelectric substrate 72B. The hollow portion overlaps at least a portion of the IDT electrode 18 in plan view.

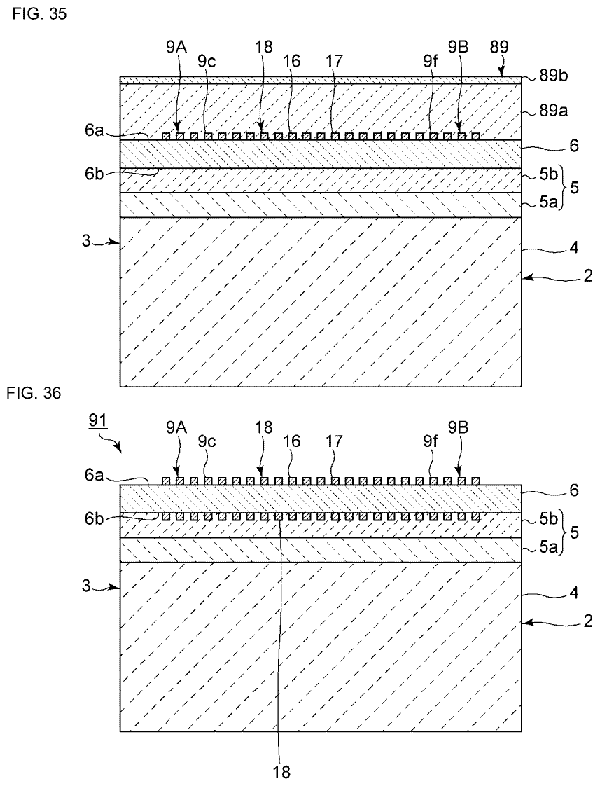

FIG. 35 is a schematic elevational cross-sectional view of an acoustic wave device according to a tenth example embodiment of the present invention.

The present example embodiment is different from the first example embodiment in that the IDT electrode 18 is embedded in a protective film 89. Except for the above point, the acoustic wave device of the present example embodiment has the same or substantially the same configuration as the acoustic wave device 1 of the first example embodiment.

Specifically, the protective film 89 is disposed on the piezoelectric layer 6 so as to cover the IDT electrode 18. The thickness of the protective film 89 is greater than that of the IDT electrode 18. The IDT electrode 18 is embedded in the protective film 89. Thus, the IDT electrode 18 is less likely to be damaged.

The protective film 89 includes a first protective layer 89a and a second protective layer 89b. The IDT electrode 18 is embedded in the first protective layer 89a. The second protective layer 89b is disposed on the first protective layer 89a. Accordingly, multiple advantageous effects can be obtained by the protective film 89. Specifically, in the present example embodiment, for example, silicon oxide is used as a material of the first protective layer 89a. This can reduce the absolute value of a temperature coefficient of frequency (TCF) in the acoustic wave device. Thus, temperature characteristics of the acoustic wave device can be improved. Silicon nitride, for example, is used for the second protective layer 89b. Accordingly, moisture resistance can be improved.

In addition, also in the present example embodiment, unwanted waves can be effectively reduced or prevented similarly to the first example embodiment.

The materials of the first protective layer 89a and the second protective layer 89b are not limited to those described above. The protective film 89 may include a single layer or a multilayer body of three or more layers.

FIG. 36 is a schematic elevational cross-sectional view of an acoustic wave device according to an eleventh example embodiment of the present invention.

The present example embodiment is different from the first example embodiment in that the IDT electrodes 18 are disposed on both of the first main surface 6a and the second main surface 6b of the piezoelectric layer 6. The IDT electrode 18 disposed on the second main surface 6b is embedded in the second layer 5b of the intermediate layer 5. Except for the above point, an acoustic wave device 91 of the present example embodiment has the same or substantially the same configuration as the acoustic wave device 1 of the first example embodiment.

The IDT electrode 18 disposed on the first main surface 6a of the piezoelectric layer 6 and the IDT electrode 18 disposed on the second main surface 6b are opposite to each other with the piezoelectric layer 6 interposed therebetween. Also in the present example embodiment, unwanted waves can be effectively reduced or prevented similarly to the first example embodiment.

The IDT electrodes 18 disposed on the first main surface 6a and the second main surface 6b of the piezoelectric layer 6 may have, for example, different design parameters from each other.

First to third modifications of the eleventh example embodiment, which are different from the eleventh example embodiment in only at least one of a configuration of an electrode disposed on the second main surface of the piezoelectric layer or a multilayer configuration of a piezoelectric substrate, are described below. Also in the first to third modifications, unwanted waves can be reduced or prevented similarly to the eleventh example embodiment.

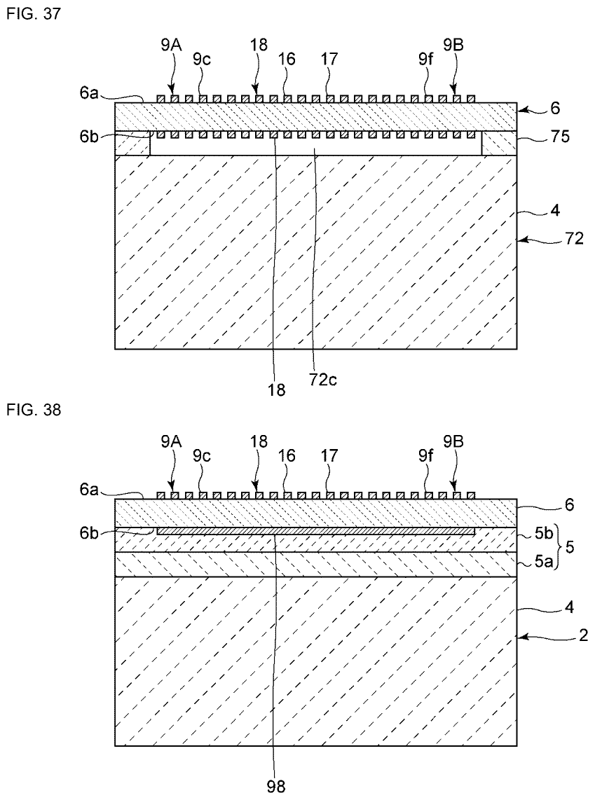

In the first modification shown in FIG. 37, the piezoelectric substrate 72 is provided similarly to the ninth example embodiment. Specifically, the piezoelectric substrate 72 includes the support substrate 4, the intermediate layer 75, and the piezoelectric layer 6. The IDT electrode 18 disposed on the second main surface 6b of the piezoelectric layer 6 is located in the hollow portion 72c.

In the second modification shown in FIG. 38, a plate-shaped electrode 98 is disposed on the second main surface 6b of the piezoelectric layer 6. The electrode 98 is embedded in the second layer 5b of the intermediate layer 5. The IDT electrode 18 and the electrode 98 are opposite to each other with the piezoelectric layer 6 interposed therebetween.

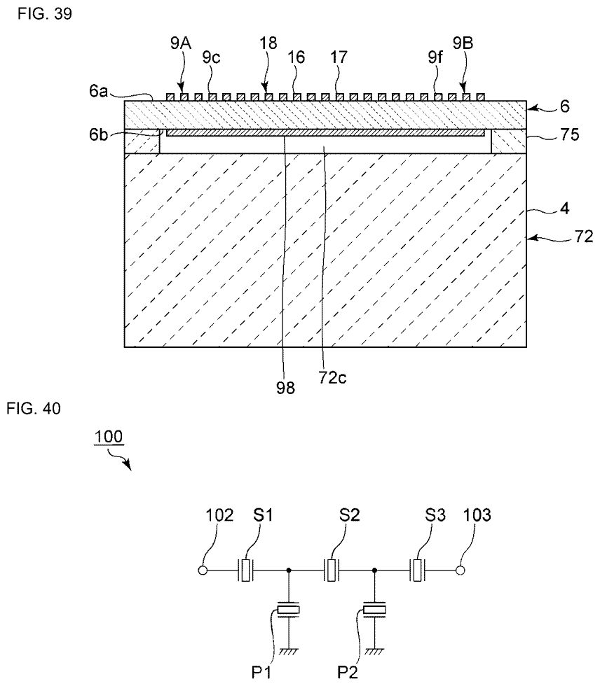

In the third modification shown in FIG. 39, the piezoelectric substrate 72 is provided similarly to the first modification, and the electrode 98 similar to that in the second modification is disposed on the second main surface 6b of the piezoelectric layer 6. The electrode 98 is located in the hollow portion 72c. The IDT electrode 18 and the electrode 98 are opposite to each other with the piezoelectric layer 6 interposed therebetween.

The acoustic wave devices according to example embodiments of the present invention can be used in, for example, a filter device. An example thereof is described below.

FIG. 40 is a circuit diagram of a filter device according to a twelfth example embodiment of the present invention.

A filter device 100 of the present example embodiment is a ladder filter, for example. The filter device 100 includes a first signal terminal 102, a second signal terminal 103, a plurality of series-arm resonators, and a plurality of parallel-arm resonators. In the filter device 100, all of the series-arm resonators and all of the parallel-arm resonators are acoustic wave resonators. Further, all of the series-arm resonators and all of the parallel-arm resonators are acoustic wave devices according to example embodiments of the present invention. However, it is sufficient that at least one of the plurality of acoustic wave resonators of the filter device 100 is an acoustic wave device according to an example embodiment of the present invention.

The first signal terminal 102 is an antenna terminal. The antenna terminal is connected to an antenna. However, the first signal terminal 102 is not necessarily required to be the antenna terminal. The first signal terminal 102 and the second signal terminal 103 may be provided, for example, as electrode pads or as wiring lines.

Specifically, the plurality of series-arm resonators of the present example embodiment are series-arm resonators S1, S2, and S3. The plurality of series-arm resonators are connected in series with each other between the first signal terminal 102 and the second signal terminal 103. Specifically, the plurality of parallel-arm resonators are parallel-arm resonators P1 and P2. The parallel-arm resonator P1 is connected between a connection point between the series-arm resonators S1 and S2 and a ground potential. The parallel-arm resonator P2 is connected between a connection point between the series-arm resonators S2 and S3 and the ground potential. A circuit configuration of the filter device 100 is not limited to that described above. The filter device 100 may include, for example, a longitudinally coupled resonator acoustic wave filter.

The acoustic wave resonator in the filter device 100 is an acoustic wave device according to an example embodiment of the present invention. Thus, unwanted waves can be effectively reduced or prevented in the acoustic wave resonator of the filter device 100. Accordingly, a filter characteristics of the filter device 100 can be improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
an interdigital transducer (IDT) electrode on the piezoelectric layer and including a pair of busbars and a plurality of electrode fingers; wherein
the pair of busbars include a first busbar and a second busbar opposite to each other, and the plurality of electrode fingers include a plurality of first electrode fingers and a plurality of second electrode fingers, one end of each of the plurality of first electrode fingers being connected to the first busbar, one end of each of the plurality of second electrode fingers being connected to the second busbar, the plurality of first electrode fingers and the plurality of second electrode fingers being interdigitated with each other;
a virtual line connecting tip portions of the plurality of second electrode fingers is defined as a first envelope, and a virtual line connecting tip portions of the plurality of first electrode fingers is defined as a second envelope, and a region between the first envelope and the second envelope in the IDT electrode is an intersection region; and
the intersection region includes a plurality of parallel regions in which the plurality of first electrode fingers and the plurality of second electrode fingers extend in parallel and a non-parallel region in which directions in which the plurality of first electrode fingers and the plurality of second electrode fingers extend intersect each other, the plurality of parallel regions and the non-parallel region being alternately arranged in at least a portion of the intersection region, the plurality of first electrode fingers and the plurality of second electrode fingers each linearly extending in the plurality of parallel regions and the non-parallel region and each being bent at boundaries between the plurality of parallel regions and the non-parallel region.

2. The acoustic wave device according to claim 1, wherein shapes of all of the first electrode fingers and all of the second electrode fingers in plan view are different from each other.

3. The acoustic wave device according to claim 1, wherein the non-parallel region connects adjacent ones of the plurality of parallel regions to each other.

4. The acoustic wave device according to claim 3, wherein
the intersection region includes three or more of the parallel regions; and
when a direction in which the plurality of first electrode fingers and the plurality of second electrode fingers extend is defined as an electrode finger extension direction, and, in three of the plurality of parallel regions that are consecutive from a first envelope side toward a second envelope side, an angle between the electrode finger extension direction in a parallel region of the plurality of parallel regions located closest to the first envelope and the electrode finger extension direction in a parallel region of the plurality of parallel regions adjacent thereto is defined as α1 and an angle between the electrode finger extension direction in the parallel region located closest to the first envelope and the electrode finger extension direction in the parallel region located closest to the second envelope is defined as α2, the plurality of parallel regions include the three of the parallel regions satisfying a relationship of α1<α2.

5. The acoustic wave device according to claim 1, wherein, when a direction in which the plurality of first electrode fingers and the plurality of second electrode fingers extend is defined as an electrode finger extension direction, and one of the plurality of parallel regions and the non-parallel region adjacent to the one of the plurality of parallel regions are defined as one set of the parallel region and the non-parallel region, and, in one set of the parallel region and the non-parallel region, a minimum value of a dimension of the parallel region along the electrode finger extension direction is defined as M1 and a maximum value of a dimension of the non-parallel region along the electrode finger extension direction in the parallel region is defined as M2, M1>M2 is satisfied in at least one set of the parallel region and the non-parallel region.

6. The acoustic wave device according to claim 5, wherein M1>M2 is satisfied in all sets of the parallel region and the non-parallel region.

7. The acoustic wave device according to claim 1, wherein, when a direction in which the plurality of first electrode fingers and the plurality of second electrode fingers extend is defined as an electrode finger extension direction, and a minimum value of a dimension of each of the plurality of parallel regions along the electrode finger extension direction is defined as M1, a maximum value among the dimensions M1 of all of the plurality of parallel regions is less than or equal to about 1.5 times a minimum value among the dimensions M1 of all of the plurality of parallel regions.

8. The acoustic wave device according to claim 1, wherein a shape of an outer peripheral edge of at least one of the plurality of parallel regions in plan view is rectangular or substantially rectangular.

9. The acoustic wave device according to claim 1, wherein a shape of an outer peripheral edge of at least one of the plurality of parallel regions in plan view is trapezoidal or substantially trapezoidal.

10. The acoustic wave device according to claim 1, wherein
when n is defined as a natural number greater than or equal to two and k is defined as each natural number from one to n, the plurality of parallel regions include k-th parallel regions, and the smaller a value of k is, the larger the number of the first electrode fingers and the second electrode fingers included in the k-th parallel region is; and
the k-th parallel regions with consecutive values of k are adjacent to each other in at least a portion of the intersection region.

11. The acoustic wave device according to claim 10, wherein n=2, and the plurality of parallel regions include a first parallel region and a second parallel region.

12. The acoustic wave device according to claim 1, wherein, when a direction in which the plurality of first electrode fingers and the plurality of second electrode fingers extend is defined as an electrode finger extension direction, at least one of a duty ratio, an electrode finger pitch, or a thickness of the plurality of first electrode fingers and the plurality of second electrode fingers is constant in a same parallel region of the plurality of parallel regions, and is different between the plurality of parallel regions different from each other in the electrode finger extension direction.

13. The acoustic wave device according to claim 1, further comprising:
a dielectric film on the piezoelectric layer and covering the IDT electrode; wherein
when a direction in which the plurality of first electrode fingers and the plurality of second electrode fingers extend is defined as an electrode finger extension direction, a thickness of the dielectric film is constant in a same parallel region of the plurality of parallel regions, and is different between the plurality of parallel regions different from each other in the electrode finger extension direction.

14. The acoustic wave device according to claim 1, wherein, in the intersection region, the plurality of first electrode fingers and the plurality of second electrode fingers each include at least two portions between which directions in which the plurality of first electrode fingers and the plurality of second electrode fingers are bent are different from each other.

15. The acoustic wave device according to claim 1, wherein resonant frequencies or anti-resonant frequencies substantially coincide with each other in the intersection region.

16. The acoustic wave device according to claim 1, wherein
the IDT electrode includes a plurality of first offset electrodes each including one end connected to the first busbar; and
the plurality of first offset electrodes are opposite to the plurality of second electrode fingers with a gap therebetween.

17. The acoustic wave device according to claim 16, wherein
between the intersection region and the first busbar, a first outer parallel region in which the first electrode finger and the first offset electrode extend in parallel or substantially in parallel and a first outer non-parallel region in which directions in which the first electrode finger and the plurality of first offset electrodes extend intersect each other are located; and
at least one of the first offset electrodes is included in at least one of the first outer parallel region and the first outer non-parallel region adjacent to the first outer parallel region, and the first offset electrode linearly extends in the first outer parallel region and the first outer non-parallel region, and is bent at a boundary between the first outer parallel region and the first outer non-parallel region.

18. The acoustic wave device according to claim 16, wherein the plurality of first offset electrodes in plan view have linear shapes in plan view.

19. The acoustic wave device according to claim 1, wherein the intersection region includes a first edge region including the first envelope, a second edge region including the second envelope, and a central region interposed between the first edge region and the second edge region, and a low acoustic velocity region in which an acoustic velocity is lower than an acoustic velocity in the central region is included in at least a portion of at least one of the first edge region or the second edge region.

20. The acoustic wave device according to claim 19, further comprising:
a mass addition film overlapping at least one of the plurality of first electrode fingers and the plurality of second electrode fingers in plan view in at least one of the first edge region or the second edge region; wherein
the low acoustic velocity region includes the mass addition film.

21. The acoustic wave device according to claim 19, wherein the low acoustic velocity region includes at least one electrode finger among the plurality of first electrode fingers and the plurality of second electrode fingers including a wide portion whose width is greater than a width in the central region in at least one of the first edge region or the second edge region.

22. The acoustic wave device according to claim 19, wherein the low acoustic velocity region includes at least one electrode finger among the plurality of first electrode fingers and the plurality of second electrode fingers having a thickness greater than a thickness in the central region in at least one of the first edge region or the second edge region.

23. The acoustic wave device according to claim 1, wherein
the first busbar includes an inner busbar portion and an outer busbar portion opposite to each other, and a plurality of connection portions connecting the inner busbar portion and the outer busbar portion;
of the inner busbar portion and the outer busbar portion, the inner busbar portion is located on an intersection region side, and the inner busbar portion extends in parallel or substantially in parallel with the first envelope; and
a plurality of openings surrounded by the inner busbar portion, the outer busbar portion, and the plurality of connection portions are provided in the first busbar.

24. The acoustic wave device according to claim 1, wherein
the piezoelectric layer includes a propagation axis; and
the first envelope extends obliquely with respect to the propagation axis.

25. The acoustic wave device according to claim 24, wherein
the second envelope extends obliquely with respect to the propagation axis; and
the first envelope and the second envelope are linear.

26. The acoustic wave device according to claim 1, wherein at least one of the first envelope or the second envelope includes at least one bending portion at which a direction in which the envelope extends changes.

27. The acoustic wave device according to claim 1, further comprising:
a pair of reflectors on the piezoelectric layer opposite to each other with the IDT electrode interposed therebetween, and each include a plurality of reflector electrode fingers; wherein
when a region obtained by extending the plurality of parallel regions in a direction in which the plurality of parallel regions extend is defined as an extension parallel region, and a region obtained by extending the non-parallel region in a direction in which the non-parallel region extends is defined as an extension non-parallel region, respective portions of each of the plurality of reflector electrode fingers of the pair of reflectors are included in a plurality of the extension parallel regions and the extension non-parallel region;
directions in which the plurality of reflector electrode fingers extend are parallel or substantially parallel to each other in the extension parallel region; and
the plurality of reflector electrode fingers linearly extend in the extension parallel region and the extension non-parallel region, and are bent at boundaries between the extension parallel region and the extension non-parallel region.

28. The acoustic wave device according to claim 1, wherein
the piezoelectric substrate includes a support substrate; and
the piezoelectric layer is located over the support substrate.

29. The acoustic wave device according to claim 28, wherein the piezoelectric substrate includes an intermediate layer between the support substrate and the piezoelectric layer.

30. The acoustic wave device according to claim 28, wherein a hollow portion is provided in the piezoelectric substrate, and a portion of the support substrate and a portion of the piezoelectric layer are opposite to each other with the hollow portion interposed therebetween.

31. The acoustic wave device according to claim 1, wherein the piezoelectric substrate includes only the piezoelectric layer.

32. A filter device comprising:
a plurality of acoustic wave resonators; wherein
at least one of the acoustic wave resonators includes the acoustic wave device according to claim 1.
